(19) United States
(12) Patent Application Publication
(10) Pub. No.: US 2012/0193995 A1
(43) Pub. Date: Aug. 2, 2012

(54) VOLTAGE GENERATION CIRCUIT, RESONANCE CIRCUIT, COMMUNICATION APPARATUS, COMMUNICATION SYSTEM, WIRELESS CHARGING SYSTEM, POWER SUPPLY APPARATUS, AND ELECTRONIC APPARATUS

(75) Inventors: Masayoshi Kanno, Tochigi (JP); Noritaka Sato, Kanagawa (JP)

(73) Assignee: SONY CORPORATION, Tokyo (JP)

(21) Appl. No.: 13/354,021

(22) Filed: Jan. 19, 2012

(30) Foreign Application Priority Data
Jan. 31, 2011 (JP) 2011-018639
Oct. 28, 2011 (JP) 2011-237251

(51) Int. Cl. H02J 17/00; H03H 2/00

(52) U.S. Cl. 307/104; 323/369; 323/370

(57) ABSTRACT

A voltage generation circuit includes: a resistor circuit which includes a plurality of resistors connected to each other in series or in parallel; a plurality of input ports which are connected in parallel to the resistor circuit and to which a control signal for controlling a potential state of the input port to one of a high state, a low state, and an open state is input; and an output port which is connected to the resistor circuit and outputs voltage signals with voltage values corresponding to combinations of the potential states of the plurality of input ports.

### CROSS REFERENCES TO RELATED APPLICATIONS

The present application claims priority to Japanese Priority Patent Application JP 2011-018639 filed in the Japan Patent Office on Jan. 31, 2011, and Japanese Priority Patent Application JP 2011-237251 filed in the Japan Patent Office on Oct. 28, 2011 the entire content of which are hereby incorporated by reference.

### BACKGROUND

The present disclosure relates to a voltage generation circuit generating a control voltage of a variable capacitance element and a resonance circuit, a communication apparatus, a communication system, a wireless charging system, a power supply apparatus, and an electronic apparatus including the voltage generation circuit.

In recent years, information processing terminals having the same function as that of a contactless type IC (Integrated Circuit) card used for, for example, a traffic passenger ticket or digital money have been widely spread. In such information processing terminals, a reception antenna (resonance circuit) installed in an information processing terminal receives a transmitted signal (electromagnetic wave) transmitted from a transmission antenna of a dedicated reader/writer (hereinafter, referred to as R/W) device by an electromagnetic induction operation.

In the information processing terminals having a contactless communication function described above, the resonance frequency of the reception antenna is varied under to the surrounding environment such as temperature, humidity, or neighboring apparatuses. In this case, it is difficult to reliably transmit and receive information between the R/W device and the information processing terminal.

Accordingly, in a technique according to the related art, the resonance frequency of the reception antenna is adjusted by a variable capacitance element provided in the reception antenna of the information processing terminal having the contactless communication function described above (for example, see Japanese Unexamined Patent Application Publication No. 2000-151457). Japanese Unexamined Patent Application Publication No. 2000-151457 discloses the technique for adjusting the resonance frequency of the reception antenna by varying a control voltage to be applied from the outside to the variable capacitance element.

### SUMMARY

In the information processing terminal having the same function (contactless communication function) as that of the contactless type IC card according to the related art, the resonance frequency of the reception antenna (resonance circuit) is adjusted by varying the control voltage to be applied to the variable capacitance element. Therefore, such an information processing terminal is mounted with a voltage generation circuit that generates the control voltage. For this reason, in the field associated with the information processing terminal having the contactless communication function, there is a demand for the development of a voltage generation circuit for controlling voltage which has a simpler and cheaper configuration.

The present disclosure is devised in the light of the above demand. It is desirable to provide a voltage generation circuit controlling voltage which has a simpler and cheaper configuration and a resonance circuit including the voltage generation circuit.

According to an embodiment of the present disclosure, there is provided a voltage generation circuit including a resistor circuit, a plurality of input ports, and an output port. The configuration and function of each unit is as follows. That is, the resistor circuit includes a plurality of resistors connected to each other in series or in parallel. The plurality of input ports are connected in parallel to the resistor circuit and to which a control signal for controlling a potential state of the input port to one of a high state, a low state, and an open state is input. The output port is connected to the resistor circuit and outputs voltage signals with voltage values corresponding to combinations of the potential states of the plurality of input ports.

According to another embodiment of the present disclosure, there is provided a resonance circuit including the voltage generation circuit described above in the embodiment of the present disclosure and a variable capacitance element which is connected to the voltage generation circuit and of which a capacitance is varied in accordance with the voltage signal output from the output port.

According to still another embodiment of the present disclosure, there is provided a communication apparatus including the voltage generation circuit described above in the embodiment of the present disclosure, a reception antenna unit, and a control unit. The configurations of the reception antenna unit and the control unit are as follows. That is, the reception antenna unit includes a resonance coil and a resonance capacitor including a variable capacitance element which is connected to the voltage generation circuit and of which a capacitance is varied in accordance with the voltage signal output from the output port and carries out contactless communication with the outside. The control unit outputs a control signal to each of the plurality of input ports.

According to further still another embodiment of the present disclosure, there is provided a communication system including a transmission apparatus and a reception apparatus carrying out contactless communication with the transmission apparatus. In the communication system according to this embodiment of the present disclosure, the transmission apparatus includes the voltage generation circuit described above in the embodiment of the present disclosure, a transmission antenna unit, and a control unit. The configurations of the transmission antenna unit and the control unit are as follows. That is, the transmission antenna unit includes a resonance coil and a resonance capacitor including a variable capacitance element which is connected to the voltage generation circuit and of which a capacitance is varied in accordance with the voltage signal output from the output port. The control unit outputs the control signal to each of the plurality of input ports.

According to further still another embodiment of the present disclosure, a wireless charging system including a power feeding apparatus and a power receiving apparatus. In the wireless charging system according to this embodiment of the present disclosure, the power feeding apparatus includes a first voltage generation circuit described above in the embodiment of the present disclosure, a power feeding antenna unit, and a first control unit. The configurations of the power feeding antenna unit and the first control unit are as follows. That is, the power feeding antenna unit includes a first resonance coil and a first resonance capacitor including a first variable capacitance element which is connected to the first voltage generation circuit and of which a capacitance is varied in accordance with the voltage signal output from the first output port. The first control unit outputs the control signal to each of the plurality of first input ports. In the wireless charging system according to this embodiment of the present disclosure, the power receiving apparatus includes a second voltage generation circuit described above in the embodiment of the present disclosure, a power receiving antenna unit, and a second control unit. The configurations of the power receiving antenna unit and the second control unit are as follows. That is, the power receiving antenna unit includes a second resonance coil and a second resonance capacitor including a second variable capacitance element which is connected to the second voltage generation circuit and of which a capacitance is varied in accordance with the voltage signal output from the second output port and carries out contactless communication with the power feeding antenna unit. The second control unit outputs the control signal to each of the plurality of second input ports.

According to further still another embodiment of the present disclosure, there is provided a power supply apparatus including a power supply unit, a rectification circuit unit, a variable impedance unit, and a control unit. The configuration of each unit is as follows. That is, the rectification circuit unit converts alternating-current power supplied from the power supply unit into direct-current power. The variable impedance unit includes the voltage generation circuit described above in the embodiment of the present disclosure and a variable capacitance element which is connected to the voltage generation circuit and of which a capacitance is varied in accordance with the voltage signal output from the output port. The variable impedance unit is provided between the power supply unit and the rectification circuit unit. The control unit outputs the control signal to each of the plurality of input ports.

According to further still another embodiment of the present disclosure, there is provided a first electronic apparatus including the voltage generation circuit described above in the embodiment of the present disclosure, a communication unit, and a control unit. The configurations of the communication unit and the control unit are as follows. That is, the communication unit includes a resonance coil and a resonance capacitor including a variable capacitance element which is connected to the voltage generation circuit and of which a capacitance is varied in accordance with the voltage signal output from the output port and carries out contactless communication with the outside. The control unit outputs the control signal to each of the plurality of input ports.

According to further still another embodiment of the present disclosure, there is provided a second electronic apparatus including a power feeding apparatus unit and a power receiving apparatus unit including the same configurations of the power feeding apparatus and the power receiving apparatus of the wireless charging system described above in the embodiment of the present disclosure.

According to further still another embodiment of the present disclosure, there is provided a third electronic apparatus including the power supply unit, the rectification circuit unit, the variable impedance unit, and the control unit of the power supply apparatus described above in the embodiment of the present disclosure.

According to further still another embodiment of the present disclosure, there is provided a fourth electronic apparatus including a communication apparatus unit having the same configuration as that of the above-described first electronic apparatus and a power feeding apparatus unit and a power receiving apparatus unit having the same configurations as those of the above-described second electronic apparatus.

According to further still another embodiment of the present disclosure, there is provided a fifth electronic apparatus including a communication apparatus unit having the same configuration as that of the above-described first electronic apparatus and a power supply apparatus unit having the same configuration as that of the above-described third electronic apparatus.

According to further still another embodiment of the present disclosure, there is provided a sixth electronic apparatus including a power feeding apparatus unit and a power receiving apparatus unit having the same configurations of those of the above-described second electronic apparatus and a power supply apparatus unit having the same configuration as that of the above-described third electronic apparatus.

According to further still another embodiment of the present disclosure, there is a provided a seventh electronic apparatus including a communication apparatus unit having the same configuration as that of the above-described first electronic apparatus, a power feeding apparatus unit and a power receiving apparatus unit having the same configurations as those of the above-described second electronic apparatus, and a power supply apparatus unit having the same configuration as that of the above-described third electronic apparatus.

According to further still another embodiment of the present disclosure, there is provided an eighth electronic apparatus including the voltage generation circuit described above in the embodiment of the present disclosure, a variable capacitance element which is connected to the voltage generation circuit and of which a capacitance is varied in accordance with the voltage signal output from the output port, and a control unit which outputs the control signal to each of the plurality of input ports.

As described above, the voltage generation circuit according to the embodiments of the present disclosure has the configuration in which the plurality of input ports and the output port are connected to the resistor circuit. Accordingly, according to the embodiments of the present disclosure, it is possible to provide the voltage generation circuit more simply at lower cost (lower price) and a resonance circuit, a communication apparatus, a communication system, a wireless charging system, a power supply apparatus, and an electronic apparatus including the voltage generation circuit.

Additional features and advantages are described herein, and will be apparent from the following Detailed Description and the figures.

### BRIEF DESCRIPTION OF THE FIGURES

FIG. 1 is a diagram illustrating the overall configuration of a resonance circuit unit according to a first embodiment;

FIG. 2 is a diagram illustrating an example of tuning characteristics of a resonance frequency;

FIG. 3 is a diagram illustrating the overall configuration of a voltage generation circuit according to the first embodiment;

FIGS. 4A and 4B are diagrams illustrating the outer appearance of an independent type resistor array;

FIG. 5 is an equivalent circuit diagram illustrating the independent type resistor array;

FIG. 6 is a diagram illustrating an example of the configuration of an adjustment table used by a first adjustment method for a control voltage according to the first embodiment;

FIG. 7 is a diagram illustrating an example of the configuration of an adjustment table used by a second adjustment method for the control voltage according to the first embodiment;

FIG. 8 is a diagram illustrating adjustment characteristics of a control voltage by the second adjustment method;

FIG. 9 is a diagram illustrating an example of the configuration of an adjustment table used according to a third adjustment method for the control voltage according to the first embodiment;

FIG. 10 is a diagram illustrating adjustment characteristics of the control voltage by the third adjustment method;

FIG. 11 is a diagram illustrating the overall configuration of a ladder-type resistor circuit used in the voltage generation circuit of a first comparison example;

FIG. 12 is a diagram illustrating the overall configuration of a DAC (Digital to Analog Converter) used in the voltage generation circuit of the first comparison example;

FIG. 13 is a diagram illustrating the overall configuration of a voltage generation circuit of a second comparison example;

FIG. 14 is a diagram illustrating the overall configuration of a voltage generation circuit according to a first modification;

FIG. 15 is a diagram illustrating an example of the configuration of an adjustment table for the control voltage according to the first modification;

FIG. 16 is a diagram illustrating an example of the configuration of an adjustment table for the control voltage according to the first modification;

FIG. 17 is a diagram illustrating adjustment characteristics of the control voltage in the voltage generation circuit according to the first modification;

FIG. 18 is a diagram illustrating the overall configuration of a voltage generation circuit according to a second modification;

FIG. 19 is a diagram illustrating the overall configuration of a voltage generation circuit according to a second embodiment;

FIGS. 20A and 20B are diagrams illustrating the outer appearance of an internal connection type resistor array;

FIG. 21 is an equivalent circuit diagram illustrating the internal connection type resistor array;

FIG. 22 is a diagram illustrating an example of the configuration of an adjustment table for a control voltage according to the second embodiment;

FIG. 23 is a diagram illustrating an example of the configuration of an adjustment table for the control voltage according to the second embodiment;

FIG. 24 is a diagram illustrating adjustment characteristics of the control voltage according to the second embodiment;

FIG. 25 is a diagram illustrating the overall configuration of a communication apparatus (according to a first application example) including the voltage generation circuit according to the embodiment of the present disclosure;

FIG. 26 is a block diagram illustrating the overall configuration of a communication system (according to a second application example) including the voltage generation circuit according to the embodiment of the present disclosure;

FIG. 27 is a block diagram illustrating the overall configuration of a wireless charging system (according to a third application example) including the voltage generation circuit according to the embodiment of the present disclosure; and

FIG. 28 is a block diagram illustrating the overall configuration of a power supply apparatus (according to a fourth application example) including the voltage generation circuit according to the embodiment of the present disclosure.

### DETAILED DESCRIPTION

Hereinafter, an example of the configuration of a voltage generation circuit according to various embodiments of the present disclosure will be described in the following order with reference to the drawings. However, the present disclosure is not limited to the following embodiments.

### 1. First Embodiment: Example of Configuration of Voltage Generation Circuit Including Resistor Circuit in Which Plurality of Resistors Are Connected to Each Other In Series

2. Second embodiment: Example of Configuration of Voltage Generation Circuit Including Resistor Circuit in Which Plurality of Resistors Are Connected to Each Other In Parallel

### 3. Various Application Examples

### 1. First Embodiment

### Configuration of Resonance Circuit Unit

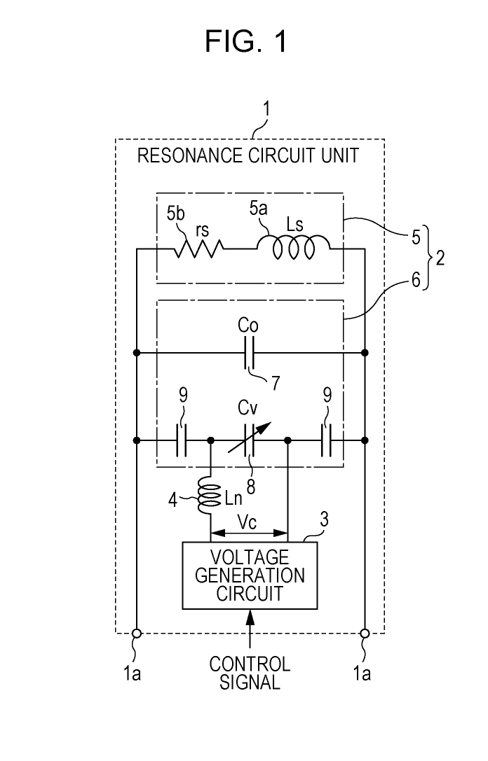

First, an example of a resonance circuit unit including a voltage generation circuit according to a first embodiment will be described before the configuration of the voltage generation circuit is described. FIG. 1 is a diagram illustrating the overall configuration of the resonance circuit unit according to this embodiment. In this embodiment, for example, a resonance circuit unit will be described which is used in a contactless type communication apparatus or the like described in a first application example described below.

A resonance circuit unit 1 (resonance circuit) includes a resonance antenna 2 (reception antenna), a voltage generation circuit 3 that applies a direct-current control voltage Vc to the resonance antenna 2, and a coil 4. The resonance circuit unit 1 receives a signal transmitted from, for example, an external R/W device (not shown) by contactless communication through the resonance antenna 2 and outputs the received signal to a rectification circuit (not shown) via two output terminals 1a.

Although not illustrated in FIG. 1, a contactless type communication apparatus according to this embodiment includes a control unit that includes, for example, a CPU (Central Processing Unit) controlling general operations. An operation of the voltage generation circuit 3, that is, an operation of adjusting a control voltage Vc is controlled by the control unit (specifically, the CPU). The internal configuration of the voltage generation circuit 3 applying the control voltage Vc to the resonance antenna 2 will be described in detail later.

The resonance antenna 2 includes a resonance coil 5 and a resonance capacitor 6. For example, the resonance coil 5 is configured by an element such as a spiral coil. The equivalent circuit of the resonance coil 5 is configured as a series circuit of an inductance component 5a (Ls) and a resistant component 5b (rs: about a few ohm) of the resonance coil 5.

The resonance capacitor 6 includes a constant capacitance capacitor 7 with capacitance Co, a variable capacitance capacitor 8 (variable capacitance element: hereinafter, simply referred to as a variable capacitor 8), and two bias removing capacitors 9 connected to both terminals of the variable capacitor 8. A series circuit formed by the constant-capacitance capacitor 7, the variable capacitor 8, and the two bias removing capacitors 9 is connected to the resonance coil 5 in parallel.

That is, the resonance antenna 2 of this example is a tunable resonance antenna in which a part of the resonance capacitor 6 is configured as the variable capacitor 8. The resonance frequency of the resonance antenna 2 of this example is calculated to be (LC)^{1/2} using an inductance L of the entire resonance coil 5 and a capacitance C of the entire resonance capacitor 6. For example, the inductance L of the entire resonance coil 5 is determined by the characteristics of a spiral coil (antenna) and a magnetic sheet (not shown) installed on the spiral coil. Further, the capacitance C of the entire resonance capacitor 6 is mainly determined by the capacitance Co of the constant-capacitance capacitor 7 and a capacitance Cv of the variable capacitor 8. However, when the resonance coil 5 is configured by a spiral coil, the inter-wiring capacitance of the spiral coil is taken into consideration.

Both the terminals of the variable capacitor 8 are connected to two output terminals of the voltage generation circuit 3, respectively. In this example, one terminal of the variable capacitor 8 is connected to one output terminal of the voltage generation circuit 3 via the coil 4.

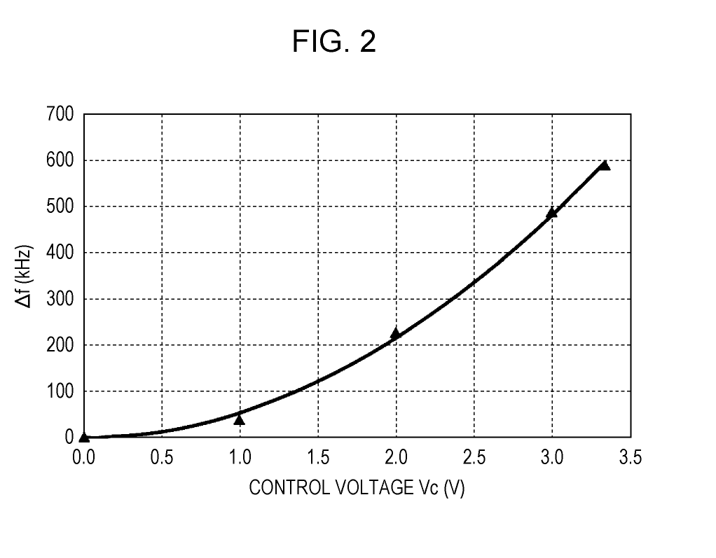

The variable capacitor 8 is made of, for example, a ferroelectric material with large relative permittivity. The capacitance Cv is varied by the control voltage Vc (voltage signal) to be applied from the voltage generation circuit 3. Specifically, when the control voltage Vc is applied from the voltage generation circuit 3, the capacitance Cv of the variable capacitor 8 is lowered. Therefore, when the control voltage Vc is applied, the resonance frequency of the resonance antenna 2 is increased (see FIG. 2 described later).

The coil 4 is installed between one terminal of the variable capacitor 8 and one output terminal of the voltage generation circuit 3. In this embodiment, an inductance Ln of the coil 4 is appropriately set so that a circuit formed by the coil 4 and the variable capacitor 8 operates as a noise filter.

FIG. 2 is a diagram illustrating an example of the tuning characteristics of the resonance frequency of the resonance antenna 2 used in this example. The horizontal axis of the tuning characteristics shown in FIG. 2 represents the value of the control voltage Vc applied from the voltage generation circuit 3 to the resonance antenna 2. The vertical axis of the tuning characteristics shown in FIG. 2 represents a shift amount Af of the resonance frequency shifted from the resonance frequency of the resonance antenna 2 when the control voltage Vc=0/0 [V]. In the resonance antenna 2 of this example, as is apparent from FIG. 2, the resonance frequency does not increase linearly, but increases nonlinearly (in the form of a quadratic curve) when the control voltage Vc increases (when the capacitance Cv of the variable capacitor 8 is lowered).

In the example shown in FIG. 2, for example, in order to adjust the resonance frequency of the resonance antenna 2 at an interval of 100 kHz, it is necessary to change and adjust the control voltage Vc to about 0.0 [V], 1.4 [V], 1.9 [V], 2.4 [V], 2.7 [V], and 3.0 [V]. In this case, it is necessary to configure the voltage generation circuit 3 so that the control voltage Vc is output at an unequal interval and an adjustment step interval of the control voltage Vc is smaller on a high-voltage side than on a low-voltage side.

### Configuration of Voltage Generation Circuit

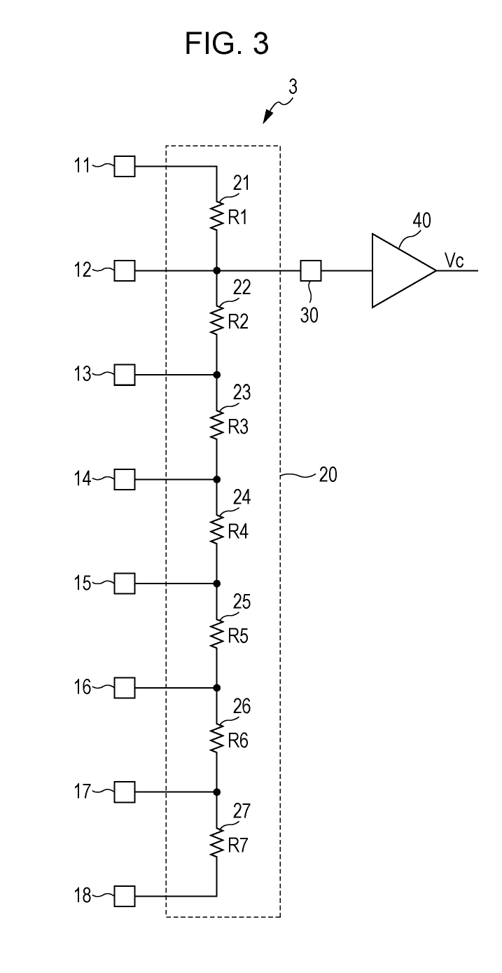

Next, the configuration of the voltage generation circuit 3 according to this embodiment will be described. FIG. 3 is a diagram illustrating the overall configuration of the voltage generation circuit 3 according to this embodiment.

The voltage generation circuit 3 includes eight input ports (a first input port 11 to an eighth input port 18), a resistor circuit 20, an output port 30, and an amplifier 40.

The first input port 11 to the eighth input port 18 are connected to the corresponding eight output ports (I/O ports) of the CPU (not shown). The potential state of each input port is set to one of a high state (3.0 [V]), a low state (0.0 [V]), and an open state (high impedance state) based on a control signal applied from the CPU. In this embodiment, a combination of the potential states of the first input port 11 to the eighth input port 18 is appropriately set based on the control signal in accordance with the value of the generated control voltage Vc.

In this example, the number of input ports is eight, but the present disclosure is not limited thereto. The number of input ports may be modified appropriately in accordance with conditions such as the intended purpose and an adjustment interval (adjustment step interval of the control voltage Vc) of the predetermined resonance frequency.

The resistor circuit 20 includes seven resistors (a first resistor 21 to a seventh resistor 27). The first resistor 21 to the seventh resistor 27 are connected to each other in series in this order. The number of resistors and the resistant values of the respective resistors are set appropriately in accordance with the conditions such as the intended purpose and an adjustment interval (adjustment step interval of the control voltage Vc) of the predetermined resonance frequency.

In this embodiment, a connection point between the resistors is connected to the corresponding input port and/or the output port 30. Specifically, one terminal of the first resistor 21 is connected to the first input port 11 and the other terminal of the first resistor 21 is connected to the second input port 12, one terminal of the second resistor 22, and the output port 30. That is, the output port 30 is connected to the connection point between the first resistor 21 and the second resistor 22.

The other terminal of the second resistor 22 is connected to the third input port 13 and one terminal of the third resistor 23. The other terminal of the third resistor 23 is connected to the fourth input port 14 and one terminal of the fourth resistor 24. The other terminal of the fourth resistor 24 is connected to the fifth input port 15 and one terminal of the fifth resistor 25. The other terminal of the fifth resistor 25 is connected to the sixth input port 16 and one terminal of the sixth resistor 26. The other terminal of the sixth resistor 26 is connected to the sixth input port 17 and one terminal of the seventh resistor 27. The other terminal of the seventh resistor 27 is connected to the eighth input port 18.

The input terminal of the amplifier 40, which is configured by, for example, a buffer amplifier (amplification factor=1), is connected to the output port 30. The amplifier 40 amplifies a voltage signal input from the connection point between the first resistor 21 and the second resistor 22 in the resistor circuit 20 via the output port 30. Then, the amplifier 40 outputs the amplified voltage signal (control voltage Vc) to the variable capacitor 8. In this example, the amplifier 40 is provided at the output end of the voltage generation circuit 3, but the present disclosure is not limited thereto. Instead, the amplifier 40 may not be provided at the output end of the voltage generation circuit 3.

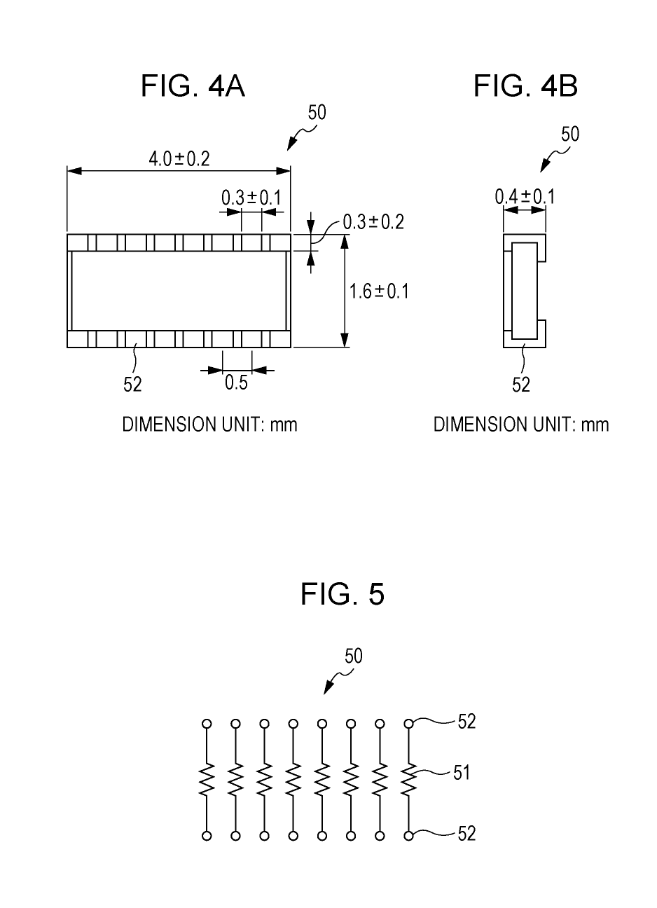

The voltage generation circuit 3 according to this embodiment in FIG. 3 may be configured by, for example, a commercially available independent type resistor array in which a plurality of resistors are mounted on a substrate. FIGS. 4A and 4B are diagrams illustrating the outer appearance of the commercially available independent type resistor array used in the voltage generation circuit 3 shown in FIG. 3. Here, FIG. 4A is a top view illustrating the independent type resistor array and FIG. 4B is a side view illustrating the short side of the independent type resistor array. FIG. 5 is a diagram illustrating an equivalent circuit of the independent type resistor array shown in FIGS. 4A and 4B.

An independent type resistor array 50 shown in FIGS. 4A, 4B, and 5 includes eight resistors 51 (resistant elements) separately mounted on a substrate (not shown). Both terminals 52 of each resistor 51 are exposed to the outside. That is, in the example shown in FIGS. 4A, 4B, and 5, sixteen terminals 52 are exposed to the outside.

The outer dimension of the resistor array 50 shown in FIGS. 4A and 4B is a length of 4.0±0.2 mm×a width of 1.6±0.1 mm×a thickness of 0.4±0.1 mm. The size of the terminal 52 exposed to the outside is 0.3±0.1 mm×0.3±0.2 mm. The pitch of the terminal 52 is 0.5 mm.

When the independent type resistor array 50 shown in FIGS. 4A, 4B, and 5 is applied to the voltage generation circuit 3 according to this embodiment, seven resistors 51 are selected and used from the eight resistors 51 of the resistor array 50. The respective terminals 52 of the selected seven resistors 51 are appropriately connected electrically to each other to manufacture the same circuit as the voltage generation circuit 3 shown in FIG. 3.

### Adjustment Method for Control Voltage

Next, various adjustment methods for the control voltage Vc in the voltage generation circuit 3 according to this embodiment will be described.

### (1) First Adjustment Method

In this embodiment, the control voltage Vc is adjusted by appropriately changing combinations of the potential states (the high state, the low state, and the open state) of the respective input ports based on the control signal input from the CPU to the voltage generation circuit 3.

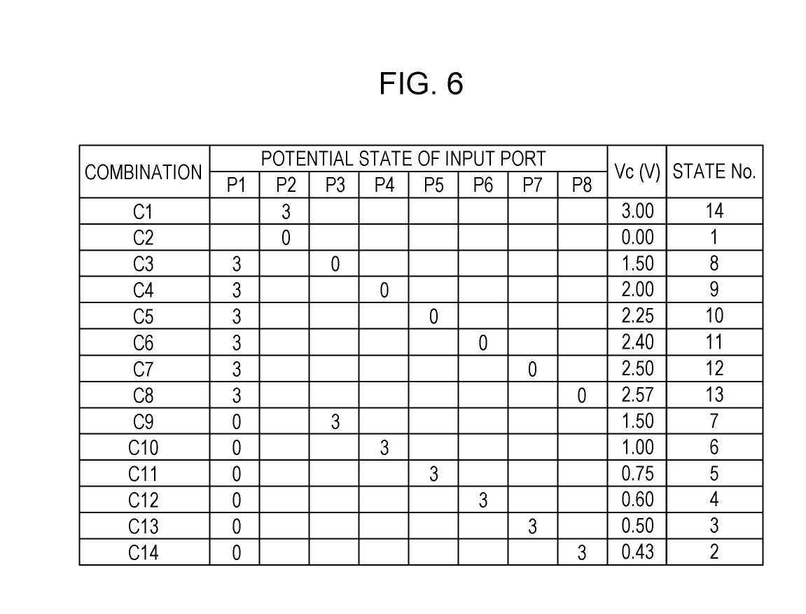

FIG. 6 shows a relation table (hereinafter, referred to as an adjustment table) between the combinations of the potential states of the respective input ports (the first input port 11 to the eighth input port 18) and the control voltages Vc generated for the combinations. The adjustment table of the control voltage Vc shown in FIG. 6 is an example when the resistant value R1 of the first resistor 21 to the resistant value R7 of the seventh resistor 27 are all the same as each other (1.0 R: reference value). Further, the reference value (1.0 R) of the resistant value is appropriately set in accordance with the conditions such as the intended purpose.

In the adjustment table shown in FIG. 6, “C1” to “C14” are combination numbers indicating the combinations of the potential states of the respective input ports. In the adjustment table shown in FIG. 6, “P1” to “P8” are port numbers of the first input port 11 to the eighth input port 18, respectively.

Further, in the adjustment table shown in FIG. 6, numeral “3” described in the column of the port numbers (“P1” to “P8”) indicates that the potential state of the input port is the high state (3.0 [V]) and numeral “0” indicates that the potential state of the input port is the low state (0.0 [V]). Further, in the adjustment table shown in FIG. 6, the blank of the column of the port numbers (“P1” to “P8”) indicates that the potential state of the input port is the open state.

In the adjustment table shown in FIG. 6, numerals “1” to “14” in the column of a “STATE No.” are indexes indicating the order of the control voltages Vc when the generated control voltages Vc are sequentially arranged from the smaller control voltage. That is, in the example shown in FIG. 6, the state number “1” is an index indicating a state when the control voltage Vc is the minimum and the state number “14” is an index indicating a state when the voltage Vc is the maximum.

In the adjustment table shown in FIG. 6, according to this embodiment, the control voltage Vc is varied when the combination (“C1” to “C14”) of the voltage state of each input port is changed based on the control signal applied to each of the first input port 11 to the eighth input port 18 of the voltage generation circuit 3.

For example, the combination “C1” in FIG. 6 indicates a case where only the second input port 12 directly connected to the output port 30 is set to the high state (3.0 [V]) and the other input ports are set to the open state. In this case, the control voltage Vc is 3.00 [V]. The combination “C2” indicates a case where only the second input port 12 is set to the low state (0.0 [V]) and the other input ports are set to the open state. In this case, the control voltage Vc is 0.00 [V].

The combinations “C3” to “C14” indicate cases where one input port among the input ports other than the second input port 12 is set to the high state (3.0 [V]) and another input port is set to the low state (0.0 [V]). Further, in the combinations “C3” to “C14”, the input ports other than the input ports which are in the high state and the low sate are set to the open state.

In the combinations “C3” to “C14”, the resistant value between the input ports which are in the high state and the low state is varied in accordance with the combination. In the combinations “C3” to “C14”, the resistant value R1 of the first resistor 21 (external resistor) corresponding to the resistant value between the input ports which are in the high state and the low state is also varied in accordance with the combination. Therefore, in the combinations “C3” to “C14”, the control voltage Vc is varied in accordance with the combination.

For example, in the combination “C5”, the control voltage Vc is 2.25 [V], when the first input port 11 is set to the high state, the fifth input port 15 is set to the low state, and the other input ports are set to the open state. On the contrary, in the combination “C11”, the control voltage Vc is 0.75 [V], when the first input port 11 is set to the low state, the fifth input port 15 is set to the high state, and the other input ports are set to the open state.

In the voltage generation circuit 3 according to this embodiment, as is apparent from the adjustment table shown in FIG. 6, there are fourteen combinations of the potential states of the first input port 11 to the eighth input port 18. However, in the combinations “C3” and “C9” (the state numbers “8” and “7”) among the combinations, the control voltages Vc (1.50 [V]) are the same as each other. Thus, when the resistant values of the first resistor 21 to the seventh resistor 27 are all set to the same value (1.0 R) in the voltage generation circuit 3, the control voltage Vc can be adjusted by the methods of the thirteen states (the number of states=13). That is, in this embodiment, the control voltages Vc can be generated by the number (=13) of states larger than the number (=8) of input ports.

From the adjustment table shown in FIG. 6, it can be understood that the control voltage Vc is varied at an unequal interval (nonlinear) in the state numbers in the voltage generation circuit 3 according to this embodiment. That is, in this embodiment, the resistant value R1 of the first resistor 21 to the resistant value R7 of the seventh resistor 27 are all the same value (1.0 R), but the control voltage Vc can be output at the unequal interval (nonlinear) in each adjustment step.

### (2) Second Adjustment Method

In the above-described first adjustment method, the example has been described in which the resistant value R1 of the first resistor 21 to the resistant value R7 of the seventh resistor 27 are all the same value (1.0 R), but the present disclosure is not limited thereto. The resistant values of the first resistor 21 to the seventh resistor 27 can be varied appropriately in accordance with the conditions such as the intended purpose and an adjustment interval (adjustment step interval of the control voltage Vc) of the predetermined resonance frequency. For example, only the resistant value R1 of the first resistor 21 (external resistor) may be configured to be different from the resistant values (R2 to R7) of the other resistors (the second resistor 22 to the seventh resistor 27).

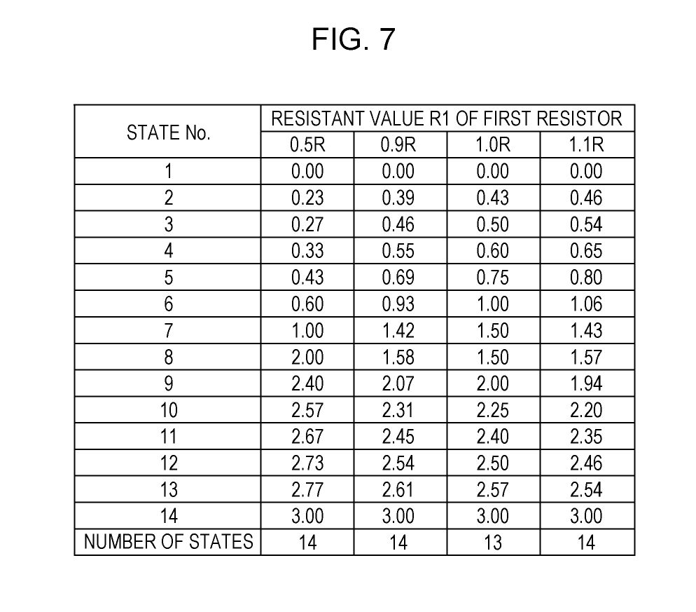

FIG. 7 shows an adjustment table of the control voltages Vc generated by the voltage generation circuit 3 when only the resistant value R1 of the first resistor 21 is varied. FIG. 7 shows an example in which the resistant value R2 of the second resistor 22 to the resistant value R7 of the seventh resistor 27 are set to 1.0 R and the resistant value R1 of the first resistor 21 is varied to 0.5 R, 0.9 R, 1.0 R, and 1.1 R. The state numbers described in the adjustment table shown in FIG. 7 correspond to state numbers of the adjustment table shown in FIG. 6. Therefore, the relationship between the state numbers described in the adjustment table shown in FIG. 7 and the combinations of the potential states of the respective input ports corresponding to the state numbers is identical to a relationship between the state numbers and the combinations in the adjustment table shown in FIG. 6. The numerals of the “STATE No.” described in the lowermost row in the adjustment table shown in FIG. 7 are the number (the number of adjustment steps) of states of the control voltage Vc which can actually be generated by the voltage generation circuit 3.

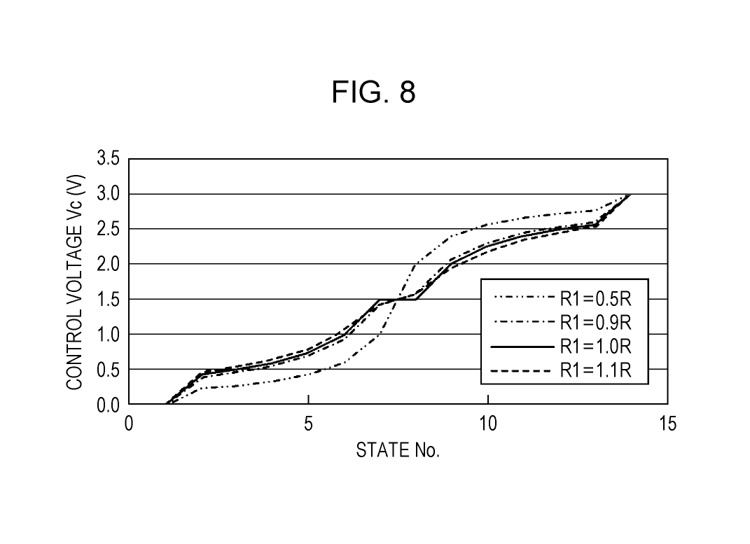

FIG. 8 shows adjustment characteristics (variation characteristics of the control voltages Vc in the state numbers of the control voltages Vc) of the control voltages Vc when the adjustment table shown in FIG. 7 is used. In the adjustment characteristic shown in FIG. 8, the vertical axis represents the control voltage Vc and the horizontal axis represents the state number corresponding to the control voltage Vc. In FIG. 8, graphs indicated by a two-dot chain line, a one-dot chain line, a solid line, and a dashed line show the characteristics when the resistant value R1 of the first resistor 21 is set to 0.5 R, 0.9 R, 1.0 R, and 1.1 R, respectively.

As is apparent from FIGS. 7 and 8, the adjustment characteristics of the control voltage Vc are changed for each resistant value R1 of the first resistor 21 by varying only the resistant value R1 of the first resistor 21. Specifically, when the resistant values (R1 to R7) of the first resistor 21 to the seventh resistor 27 are all the same value, the control voltages Vc in the state numbers “7” and “8” have the same value (1.50 [V]). However, when only the resistant value R1 of the first resistor 21 is varied, the control voltages Vc in the state numbers “7” and “8” have different values.

Therefore, in the voltage generation circuit 3 according to this embodiment, the control voltages Vc can be generated by the methods of fourteen states (the number of states=14), when the resistant value R1 of the first resistor 21 is configured to be different from the resistant values of the other resistors. That is, in this embodiment, it is possible to easily increase the number of states (number of adjustment steps) of the generable control voltage Vc by varying only the resistant value R1 of the first resistor 21.

In this embodiment, as is apparent from FIGS. 7 and 8, for example, the adjustment characteristics of the control voltage Vc on the high-voltage side subsequent to the state number “8” are varied nearly logarithmically irrespective of the resistant value R1 of the first resistor 21. Thus, it can be understood that the voltage generation circuit 3 according to this embodiment is, for example, a circuit that is satisfactorily compatible with a contactless type communication apparatus with tuning characteristics of a resonance frequency in the form of the quadratic curve shown in FIG. 2.

(3) Third Adjustment Method

When the resonance frequency is adjusted at an equal frequency interval in the contactless type communication apparatus having the tuning characteristics of the resonance frequency in the form of the quadratic curve shown in FIG. 2, as described above, the adjustment step interval of the control voltage Vc is preferably smaller on the high-voltage side than on the low-voltage side. Therefore, in the contactless type communication apparatus having the tuning characteristics of the resonance frequency in the form of the quadratic curve shown in FIG. 2, for example, the variation in the control voltage Vc is preferably smaller on the high-voltage side in the adjustment characteristics of the control voltage Vc shown in FIG. 8.

However, in the first and second adjustment methods for the control voltage Vc described above, as shown in FIG. 8, the variation in the control voltage Vc is relatively large between the state number “14” in which the control voltage Vc is the maximum (3.0 [V]) and the state number “13” immediately before the state number “14”. That is, when the maximum value (the maximum voltage value of a voltage signal to be output from the output port 30) of the control voltage Vc necessary for capacitance adjustment of the variable capacitor 8 is 3.0 [V], the variation in the control voltage Vc is relatively large between the state numbers in the vicinity of the maximum value of the control voltage Vc. Therefore, when the voltage generation circuit 3 according to this embodiment is applied to the contactless type communication apparatus having the tuning characteristics of the resonance frequency in the form of the quadratic curve shown in FIG. 2, there is a possibility that it is difficult to adjust the control voltage Vc on the high-voltage side.

Accordingly, in a third adjustment method, the potential of a high state of the input port of the voltage generation circuit 3 is configured to be larger than the maximum value of the necessary control voltage Vc in order to allow the variation in the control voltage Vc to be small between the state numbers in the vicinity of the maximum value (3.0 [V]) of the control voltage Vc.

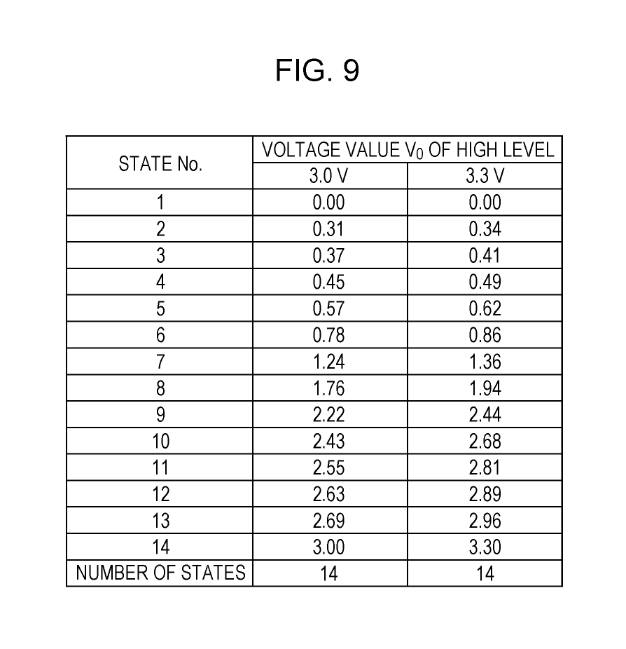

FIG. 9 is a diagram illustrating an adjustment table indicating a relationship between a voltage value V₀ in the high state of the input port and the control voltage Vc generated by the voltage generation circuit 3. FIG. 9 shows an example of the adjustment table for the control voltage Vc when the voltage value V₀ in the high state of the input port is changed into 3.0 [V] and 3.3 [V]. Here, FIG. 9 shows an example in which the resistant value R2 of the second resistor 22 to the resistant value R7 of the seventh resistor 27 are set to 1.0 R and the resistant value R1 of the first resistor 21 is set to 0.7 R. That is, an example of the combination of the above-described second adjustment method and the third adjustment method is shown.

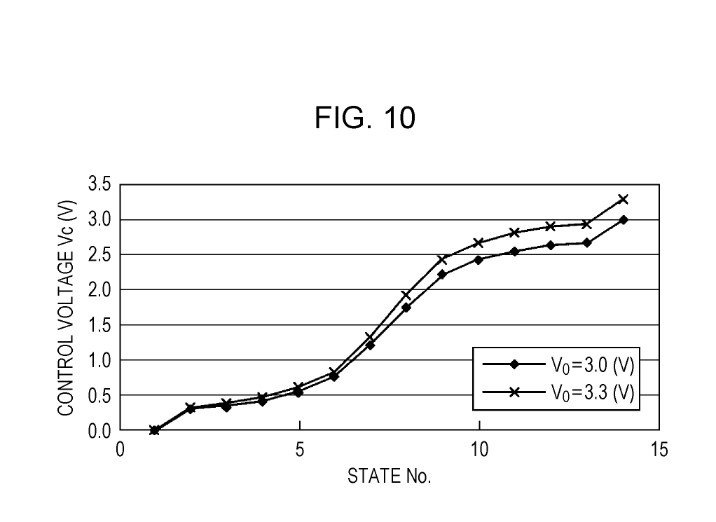

FIG. 10 is a diagram illustrating the adjustment characteristics of the control voltage Vc when the adjustment table shown in FIG. 9 is used. In the characteristics shown in FIG. 10, the vertical axis represents the control voltage Vc and the horizontal axis represents a state number corresponding to the control voltage Vc. In FIG. 10, graphs indicated by a rhombic mark and a cross mark represent the adjustment characteristics of the control voltage Vc when the voltage value V₀ in the high state of the input port are set to 3.0 [V] and 3.3 [V], respectively.

As is apparent from FIG. 10, the adjustment characteristics on the high-voltage side of the control voltage Vc are shifted to the high-voltage side, when the voltage value V₀ in the high state of the input port is increased. The control voltage Vc is equal to 2.96 [V] in the state number “13” immediately before the state number “14” when the voltage value V0 in the high state of the input port is 3.3 [V]. Therefore, when the voltage value V0 in the high state of the input port is set to 3.3 [V], the variation in the control voltage Vc can be made to be small in the state numbers in the vicinity of the maximum value (3.0 [V]) of the control voltage Vc.

In this case, the number of states (the number of adjustment steps) of the control voltage Vc actually output from the voltage generation circuit 3 is thirteen. Therefore, when the voltage value V₀ in the high state of the input port is set to 3.0 [V], the number of states of the control voltage Vc is decreased from the number (14) of states. However, for example, when the resonance frequency is adjusted at an equal interval in the contactless type communication apparatus using the tuning characteristics shown in FIG. 2, the control voltage Vc on the high-voltage side can easily be adjusted by using the third adjustment method, thereby improving adjustment accuracy.

Specifically, for example, it is considered that the resonance frequency is adjusted at a 100 kHz interval in the contactless type communication apparatus having the tuning characteristics shown in FIG. 2. In this case, as described above, it is necessary to change and adjust the control voltage Vc to 0.0 [V], 1.4 [V], 1.9 [V], 2.4 [V], 2.7 [V], and 3.0 [V]. On the other hand, in this embodiment, the control value V₀ in the high state of the input port is first set to 3.3 [V]. When the state numbers “1”, “7”, “8”, “9”, “10”, and “13” are selected, the control voltages of 0.0 [V], 1.36 [V], 1.94 [V], 2.44 [V], 2.68 [V], and 2.96 [V] can be obtained respectively. That is, in the voltage generation circuit 3 according to this embodiment, the adjustment of the control voltage Vc suitable for the tuning characteristics shown in FIG. 2 can be realized by setting the voltage value V0 in the high state of the input port to 3.3 [V].

Further, the voltage value V₀ in the high state of the input port, that is, 3.3 [V] used here is generally a voltage value of a power source used to control various operations performed in the contactless type communication apparatus. Therefore, when the voltage value V₀ in the high state applied to the input port of the voltage generation circuit 3 is set to 3.3 [V], a power source used to control other various operations can be used also in the operation of adjusting the resonance frequency. That is, in this case, it is not necessary to provide a power source adjusting the resonance frequency.

In this embodiment, as described above, for example, only the resistant value of the external resistor such as the first resistor 21 is varied. Further, as described above, for example, the voltage value V₀ in the high state of the input port is varied, that is, the second and third adjustment methods are combined. However, the present disclosure is not limited thereto. For example, the resistant values of all the resistors may be made to be equal to each other and the number of states (the number of adjustment steps) of the generable control voltage Vc and the adjustment characteristics may be adjust by varying the voltage value V₀ in the high state of the input port.

The operation of adjusting the control voltage Vc described in the first to third adjustment methods is controlled by a control unit (including a CPU) of the contactless type communication apparatus. Specifically, various adjustment tables shown in FIGS. 6, and 7 and/or 9 are stored in advance in the control unit and the CPU adjusts the control voltage Vc by controlling the combinations of the potential states of the plurality of input ports installed in the voltage generation circuit 3 based on the adjustment tables. In this embodiment, the process of adjusting the control voltage Vc may be controlled by feedback while monitoring the variation in the resonance frequency.

In the first to third adjustment methods, as described above, for example, the resonance frequency is adjusted at the 100 kHz interval (adjustment steps), but the present disclosure is not limited thereto. The adjustment steps of the resonance frequency may be changed in accordance with a condition such as the intended purpose. For example, when the adjustment steps of the resonance frequency are further divided, the resistant values of the respective resistors in the resistor circuit 20 may appropriately be changed or the number of resistors may be increased.

### Various Comparison Examples

In this embodiment, the voltage generation circuit 3 can be provided more simply at low cost (low price) by embodying the above-described configuration of the voltage generation circuit 3. The configuration of the voltage generation circuit 3 provided more simply at low cost will be described in comparison with various comparison examples.

### (1) First Comparison Example

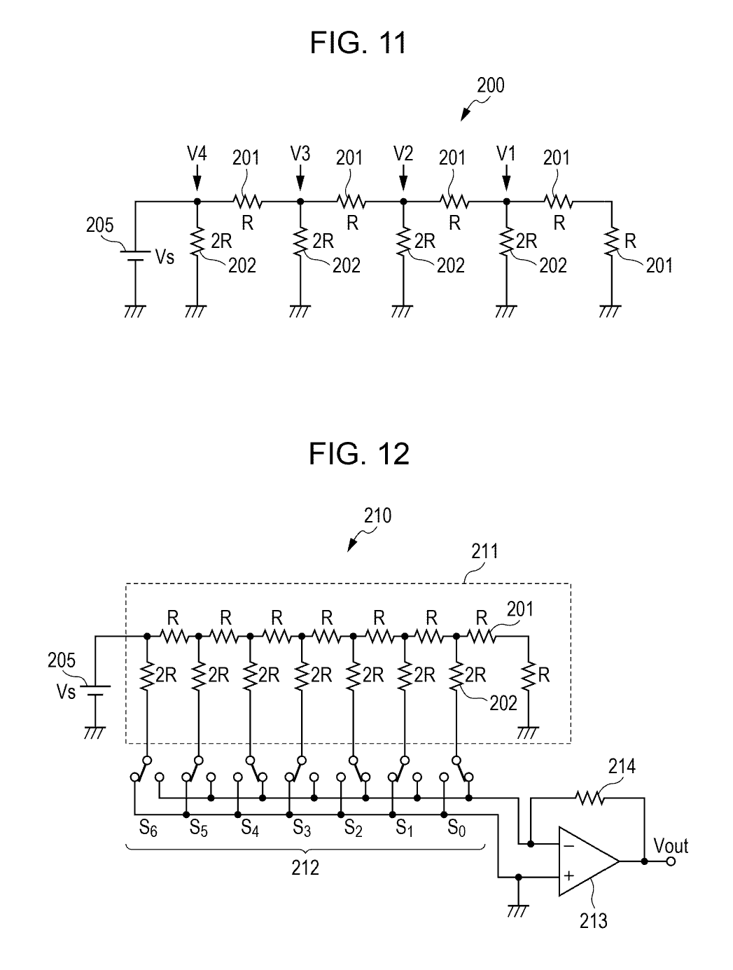

A DAC (first comparison example) can be used as a circuit generating the control voltage Vc to be applied the variable capacitor 8. In general, a ladder-type resistor circuit is used in the DAC. FIG. 11 is a diagram illustrating the overall configuration of the ladder-type resistor circuit (R-2R ladder-type resistor circuit) used in the DAC.

A ladder-type resistor circuit 200 shown in FIG. 11 include five first resistors 201 with a resistant value R and four second resistors 202 with a resistant value 2 R.

In the example shown in FIG. 11, the five first resistors 201 are connected to each other in series. A power source 205 of a DAC is connected to one terminal of a series circuit including the five first resistors 201 and the other terminal of the series circuit is grounded. One terminal of each of the second resistors 202 is connected to a connection point between the corresponding first resistors 201 and the other terminal of each of the second resistors 202 is grounded. Here, the second resistor 202 is not connected to the connection point between the first resistors 201 located on the ground side of the series circuit including the five first resistors 201. In the example shown in FIG. 11, the plurality of first resistors 201 and the plurality of second resistors 202 are connected to each other in a ladder form in this way.

In the DAC using the ladder-type resistor circuit 200 shown in FIG. 11, a switch circuit unit (not shown) selects a predetermined connection point from the connection points between the plurality of first resistors 201 and the second plurality of resistors 202 and outputs voltage signals with different voltage values (voltages V1 to V4 in FIG. 11).

Hereinafter, the configuration of the DAC using a R-2R ladder-type resistor circuit will be described in more detail with reference to FIG. 12. FIG. 12 is a diagram illustrating the overall configuration of the DAC using the R-2R ladder-type resistor circuit. In FIG. 12, the R-2R ladder-type resistor circuit has the same configuration as that of the ladder-type resistor circuit 200 and the peripheral circuit shown in FIG. 11. The same reference numerals are given to the same constituent elements as those of the configuration.

A DAC 210 includes a ladder-type resistor circuit 211, a power source 205, a switch circuit unit 212, a differential amplifier 213, and a resistor 214 provided between an output terminal and a negative input terminal of the differential amplifier 213. The resistant value of the resistor 214 is R.

The ladder-type resistor circuit 211 includes eight first resistors 201 with a resistant value R and seven second resistors 202 with a resistant value 2R. These resistors are connected to each other in a ladder form. In the example shown in FIG. 12, the number of first resistors 201 and second resistors 202 is larger than the number of resistors in the example shown in FIG. 11, so that the number of bits of the DAC 210 is eight. Further, the ladder-type resistor circuit 211 shown in FIG. 12 has the same configuration as that of the ladder-type resistor circuit 200 shown in FIG. 11 except that the number of first resistors 201 and second resistors 202 is increased.

The switch circuit unit 212 includes seven switches S₀ to S₆. Each switch is connected to the other terminal (terminal which is not connected to the first resistor 201) of the corresponding second resistor 202. Two output terminals of the switch circuit unit 212 are connected to positive and negative input terminals of the differential amplifier 213, respectively.

In the DAC 210 having the above-described configuration, an output voltage Vout corresponding to a connection state of each switch is output from the differential amplifier 213 by changing the connection state of each switch in the switch circuit unit 212. Specifically, a “0” state is formed when each switch in FIG. 12 is switched to the left side and the second resistor 202 is thus connected to the positive terminal (GND) of the differential amplifier 213. On the other hand, a “1” state is formed when each switch in FIG. 12 is switched to the right side and a current flows to the negative terminal (virtual ground) of the differential amplifier 213. In the DAC 210 shown in FIG. 12, the voltage corresponding to the amount of current flowing to the virtual ground is output from the differential amplifier 213.

However, in the contactless type communication apparatus, for example, the resonance frequency is not changed linearly with respect to the control voltage Vc applied to the variable capacitor 8, as the tuning characteristics of the resonance frequency is described above with reference to FIG. 2. Therefore, when the resonance frequency is adjusted at an equal interval in the contactless type communication apparatus having the tuning characteristics of the resonance frequency described with reference to FIG. 2, it is necessary for the voltage generation circuit to generate the control voltage Vc so that the adjustment step interval of the control voltage Vc is an unequal interval (irregular variation amount) of the control voltage Vc.

In contrast, since the variation characteristics of the output voltage Vout of the DAC 210 shown in FIG. 12 are excellent in the linearity, the adjustment step interval of the output voltage Vout is an equal interval (regular variation amount). Therefore, for example, when the DAC 210 is applied to the contactless type communication apparatus having the tuning characteristics of the nonlinear resonance frequency shown in FIG. 2, the adjustment interval of the resonance frequency is not regular.

Specifically, when the number of adjustment steps (the number of states) of the predetermined resonance frequency is eight in the tuning characteristics of the nonlinear resonance frequency described with reference to FIG. 2, the control voltage Vc can be varied by eight methods by the DAC 210 of three bits. However, the adjustment step interval of the output voltage Vout of the DAC 210 is the equal interval, as described above. Therefore, when the DAC 210 of three bits is used as the voltage generation circuit generating the control voltage Vc, the adjustment interval of the resonance frequency can be made to be regular.

In order to resolve the defect of the DAC 210, it is necessary to increase the number of bits of the DAC 210 and increase the number of states (the number of adjustment steps) of the generable output voltage Vout. For example, since the DAC 210 of eight bits shown in FIG. 12 can output the output voltage Vout by 256 methods, the output voltage Vout by which the adjustment interval of the resonance frequency is regular may be selected as the control voltage Vc. In this method, however, since the number of resistors and the number of switches in the DAC 210 are increased, the cost is increased.

Currently, a DAC of a low speed is available, for example, at the low prices of 20 yen or less in a market. However, this DAC 210 has superfluous qualities and is expensive, for example, when the adjustment steps of the control voltage Vc are necessary through about six to eight methods as in the default resonance frequency in the shipment of the contactless type communication apparatus.

Further, the same number of switch control signals as the number of switches installed in the DAC 210 is necessary in the control of the DAC 210. Therefore, when the number of switches in the DAC 210 is increased, the number of switch control signals is also increased, thereby complicating the circuit configuration.

In contrast, in the voltage generation circuit 3 according to this embodiment, it is not necessary to provide the switches which are used in the DAC 210, as shown in FIG. 3. Thus, in the voltage generation circuit 3 according to this embodiment, the cost can be reduced compared to the case (first comparison example) where the DAC 210 is used as a circuit generating the control voltage Vc. Further, in this embodiment, since the voltage generation circuit 3 is provided with no switch, the configuration of the voltage generation circuit 3 can be realized more simply and in a space-saving manner compared to the first comparison example.

(2) Second Comparison Example

A voltage generation circuit (second comparison example) using a resistance division method can also be used as the circuit generating the control voltage Vc.

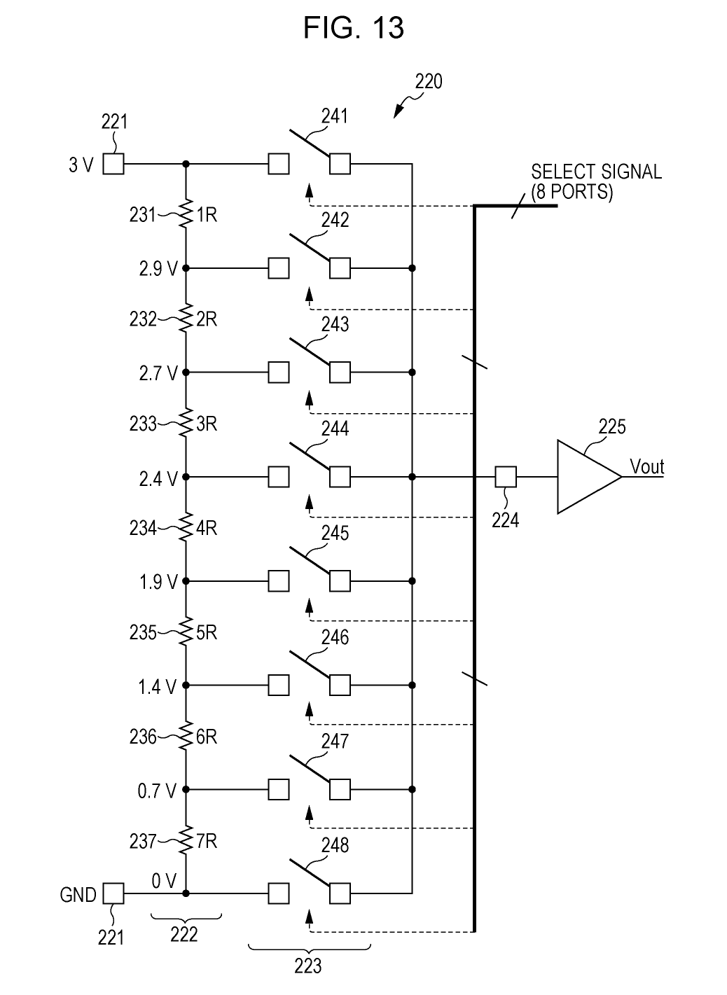

FIG. 13 is a diagram illustrating the overall configuration of a voltage generation circuit of a second comparison example. In this example, a voltage generation circuit 220 includes two input ports 221, a resistor circuit 222, a switch circuit unit 223, an output port 224, and an amplifier 225.

A predetermined direct-current voltage (3.0 [V] in the example shown in FIG. 13) is supplied to one input port 221 of the two input ports 221. The other input port 221 is grounded.

The resistor circuit 222 includes seven resistors (a first resistor 231 to a seventh resistor 237) and is configured by connecting the first resistor 231 to the seventh resistor 237 to each other in series in this order. In the example shown in FIG. 13, the resistant value of the first resistor 231 is set to 1 R (reference value). The resistant values of the second resistor 232 and the third resistor 233 are set to 2 R and 3 R, respectively. In the example shown in FIG. 13, the resistant values of the fourth resistor 234 and the fifth resistor 235 are set to 5 R together and the resistant values of the sixth resistor 236 and the seventh resistor 237 are set to 7 R together.

The terminal of the first resistor 231 opposite to the second resistor 232 is connected to the one input port 221 (input port to which a predetermined direct-current voltage is applied) and the input terminal of a first switch 241 described below. On the other hand, the terminal of the seventh resistor 237 opposite to the sixth resistor 236 is connected to the other input port 221 (input port grounded) and the input terminal of an eighth switch 248 described below.

The switch circuit unit 223 includes eight switches (a first switch 241 to an eighth switch 248). The input terminal of each of the second switch 242 to the seventh switch 247 is connected to the connection point between the corresponding resistors. The output terminal of each of the first switch 241 to the eighth switch 248 is connected to the input terminal of the amplifier 225 via the output port 224. In this example, the ON/OFF operations of the first switch 241 to the eighth switch 248 are controlled by select signals (indicated by dashed lines in FIG. 13) output from the output port of an external control unit (for example, a CPU).

In the voltage generation circuit 220 of this example, as described above, the potentials of the input ends of the first switch 241 to the eighth switch 248 are set to 3.0 [V], 2.9 [V], 2.7 [V], 2.4 [V], 1.9 [V], 1.4 [V], 0.7 [V], and 0.0 [V], respectively, by weighting the resistant values of the respective resistors. That is, the voltage generation circuit 220 of this example can selectively output the output voltages Vout of 0.0 [V], 0.7 [V], 1.4 [V], 1.9 [V], 2.4 [V], 2.7 [V], 2.9 [V], and 3.0 [V] by the select signals, so that the step interval of the output voltages can be made to be unequal. Therefore, in the second comparison example, the tuning characteristics of the nonlinear resonance frequency shown in FIG. 2 can be realized without increasing the number of resistors or switches, compared to the configuration (in which the DAC 210 is used) of the first comparison example.

As described above, the voltage generation circuit 220 of the second comparison example is configured more simply at low cost compared to the first comparison example. However, in this example, it is also necessary to provide the switches in the voltage generation circuit 220 as in the first comparison example.

In the voltage generation circuit 3 according to this embodiment, however, it is not necessary to provide the switches in the voltage generation circuit 3, as described above. Thus, the cost of the voltage generation circuit 3 according to this embodiment can be reduced more than that of the voltage generation circuit 220 of the second comparison example. Further, since the voltage generation circuit 3 according to this embodiment is provided with no switch, the voltage generation circuit 3 can be configured more simply in a space-saving manner, compared to the voltage generation circuit of the second comparison example.

In the voltage generation circuit 3 according to this embodiment, for example, the following advantages can be obtained as well as the above-described advantage. In the voltage generation circuit 220 of the second comparison example, the values of the generable output voltages Vout are determined by the resistant values of the respective resistors and the number of states (the number of adjustment steps) of the output voltage Vout are determined by the number of switches (the number of resistors). Specifically, the number of states of the output voltage Vout generated by the voltage generation circuit 220 of the second comparison example is equal to the number of switches or the number of select signals (the number of output ports of the CPU connected to the voltage generation circuit 220) of the switches.

Therefore, in order to increase the number of states (the number of adjustment steps) of the output voltage Vout in the voltage generation circuit 220 of the second comparison example, it is necessary to increase the number of resistors, the number of switches, and the number of select signals. Therefore, when the voltage generation circuit 220 of the second comparison example is applied to a case where it is necessary to adjust the resonance frequency (the control voltage Vc) of the resonance circuit more minutely, the number of resistors, the number of switches, the number of select signals are also increased.

In contrast, the voltage generation circuit 3 according to this embodiment can generate the control voltages Vc of the number of states larger than the number of resistors and the number of input ports (the number of output ports of the CPU connected to the voltage generation circuit 3), as described above. Thus, the voltage generation circuit 3 according to this embodiment can adjust the resonance frequency of the resonance circuit more minutely without increasing the number of resistors and the number of input ports.

In the voltage generation circuit 220 of the second comparison example, in order to make the output characteristics of the output voltage Vout nonlinear, it is necessary to use plural kinds of resistors having different values as described in FIG. 13. In contract, in the voltage generation circuit 3 according to this embodiment, it is possible to obtain the advantage of making the output characteristics (adjustment characteristics) of the control voltage Vc nonlinear, even when the resistant values of the plurality of resistors are made to be equal to each other.

### First Modification

In the above-described first embodiment, as described above, for example, the output port 30 is connected to the second input port 12, but the present disclosure is not limited thereto. For example, the output port 30 may be connected to one of the third input port 13 to the seventh input port 17.

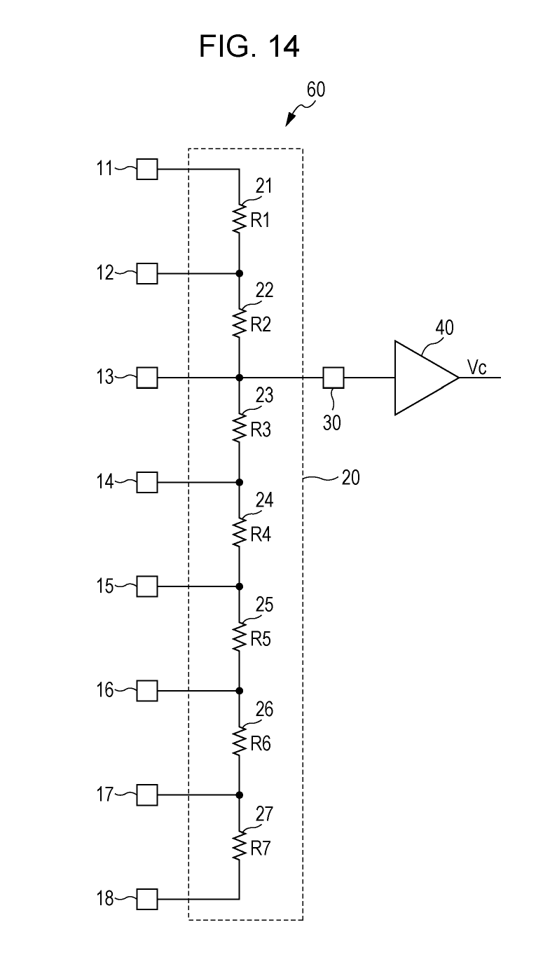

In a first modification, an example will be described in which the output port 30 is connected to the third input port 13. FIG. 14 is a diagram illustrating the overall configuration of a voltage generation circuit according to the first modification. In a voltage generation circuit 60 of the first modification shown in FIG. 14, the same reference numerals are given to the same constituent elements in the same configuration as that of the voltage generation circuit 3 described in FIG. 3 according to the first embodiment.

The voltage generation circuit 60 of this example includes a first input port 11 to an eighth input port 18, a resistor circuit 20, an output port 30, and an amplifier 40. In this example, the output port 30 is connected to the third input port 13, that is, the connection point between a second resistor 22 and a third resistor 23. Further, as is apparent from comparison between FIGS. 14 and 3, the voltage generation circuit 60 of this example has the same configuration as that of the above-described voltage generation circuit 3 (see FIG. 3) according to the first embodiment except for a change in the input port to which the output port 30 is connected.

In this example, the control voltage Vc can be adjusted by appropriately changing the combinations of the potential states (the high state, the low state, and the open state) of the respective input port (the first input port 11 to the eighth input port 18) of the voltage generation circuit 60.

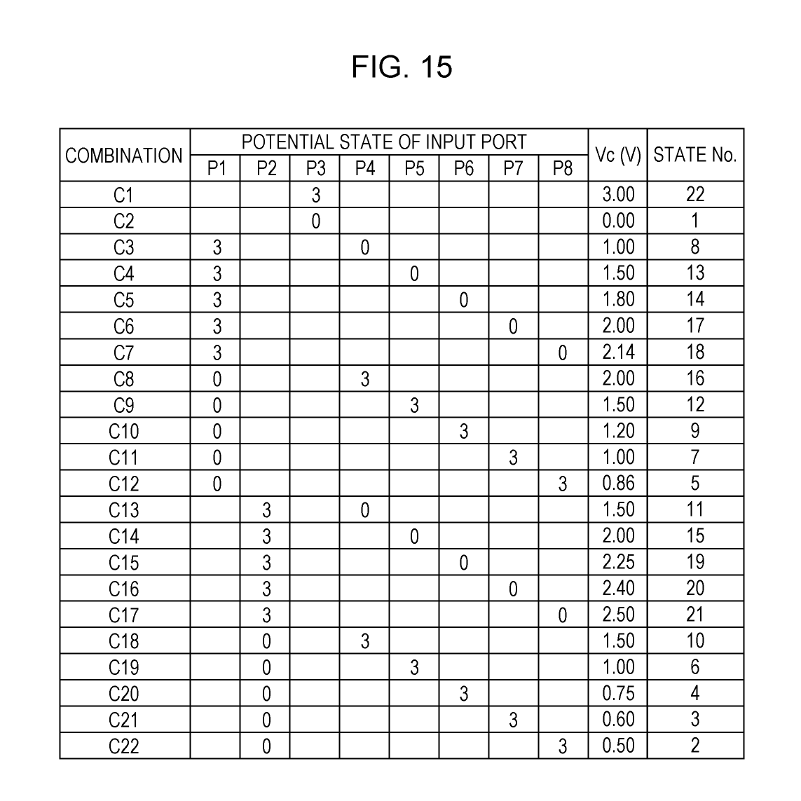

FIG. 15 is a diagram illustrating an adjustment table indicating a relationship between the combinations of the potential states of the respective ports and the control voltages Vc to be output in the combinations. In the adjustment table of the control voltages Vc shown in FIG. 15, the resistant values of the first resistor 21 to the seventh resistor 27 are all set to the same value (1.0 R). In this example, the potential in the high state of the input port is set to 3.0 [V] and the potential in the low state of the input port is set to 0.0 [V].

As is apparent from the adjustment table shown in FIG. 15, in the voltage generation circuit 60 of this example, there are twenty two combinations of the potential states of the respective input ports. However, the control voltages Vc are 1.00 [V] in combinations “C19”, “C11”, and “C3” (state numbers “6” to “8”). Further, the control voltages Vc are 1.50 [V] in the combinations “C18”, “C13”, “C9”, and “C4” (state numbers “10” to “13”). Furthermore, the control voltages Vc are 2.00 [V] in combinations “C14”, “C8”, and “C6” (state numbers “15” to “17”). Therefore, when the resistant values of the first resistor 21 to the seventh resistor 27 are all set to the same value (1.0 R) in the voltage generation circuit 60, the control voltage Vc can be adjusted by fifteen methods (number of states=15).

In the voltage generation circuit 60 of this example, as described above, the control voltages Vc of the number of states (the number of adjustment steps) larger than the number of input ports (or the number of resistors) can also be generated by changing the combinations of the potential states of the respective input ports. In this example, by just changing the input port to which the output port 30 is connected from the second input port 12 to the third input port 13, it is possible to increase the number of states of the control voltage Vc, compared to the first embodiment.

In this example, the resistant values of the first resistor 21 to the seventh resistor 27 may also be changed appropriately in accordance with the conditions such as the intended purpose. For example, only the resistant value R1 of the first resistor 21 may be different from the resistant values of the other resistors.

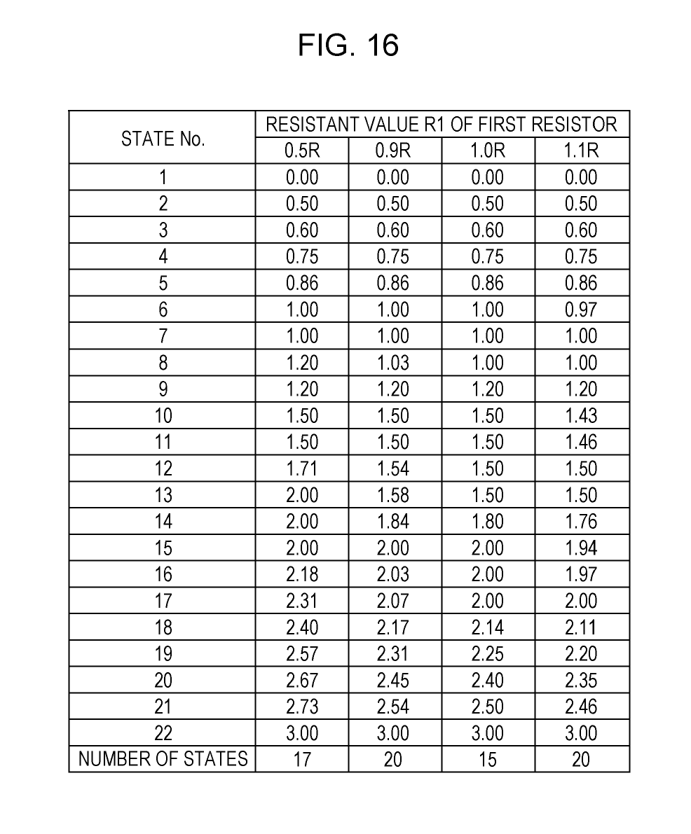

FIG. 16 is a diagram illustrating an adjustment table of the control voltages Vc generated by the voltage generation circuit 60 when only the resistant value R1 of the first resistor 21 is varied. FIG. 16 shows an example in which the resistant value R2 of the second resistor 22 to the resistant value R7 of the seventh resistor 27 are set to 1.0 R and the resistant value R1 of the first resistor 21 is changed to 0.5 R, 0.9 R, 1.0 R, and 1.1 R.

In this example, as is apparent from the adjustment table shown in FIG. 16, the number of states of the control voltage Vc can be increased up to twenty by varying only the resistant value R1 of the first resistor 21. That is, in this example, the number of states of the generable control voltage Vc can easily be increased by varying only the resistant value R1 of the first resistor 21 (external resistor) as well, as in the above-described first embodiment.

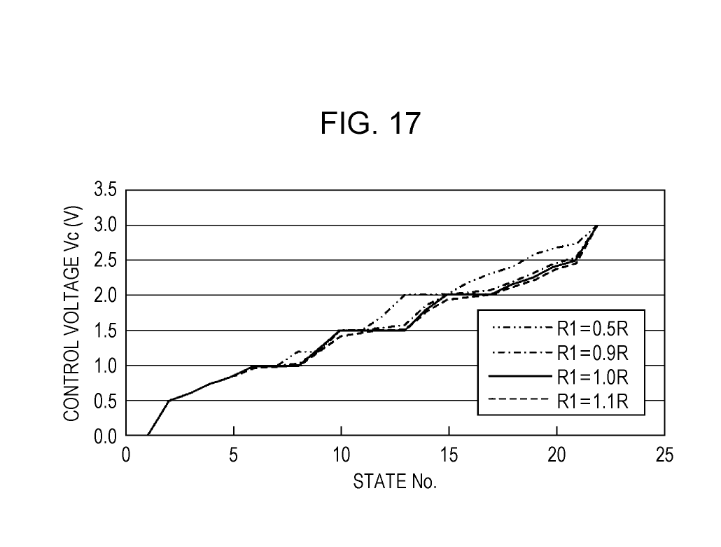

FIG. 17 shows adjustment characteristics (variation characteristics of the control voltages Vc in the state numbers of the control voltages Vc) of the control voltages Vc when the adjustment table shown in FIG. 16 is used. In the adjustment characteristic shown in FIG. 17, the vertical axis represents the control voltage Vc and the horizontal axis represents the state number corresponding to the control voltage Vc. In FIG. 17, graphs indicated by a two-dot chain line, a one-dot chain line, a solid line, and a dashed line show the characteristics when the resistant value R1 of the first resistor 21 is set to 0.5 R, 0.9 R, 1.0 R, and 1.1 R, respectively.

In this example, as is apparent from FIG. 17, the adjustment characteristics of the control voltage Vc are changed for each resistant value R1 of the first resistor 21 by varying only the resistant value R1 of the first resistor 21, as in the above-described first embodiment. Further, as is apparent from comparison between the adjustment characteristics (see FIG. 17) of the control voltage Vc of this example and the adjustment characteristics (see FIG. 8) of the control voltage Vc described above in the first embodiment, the linearity of the adjustment characteristics of the control voltage Vc of this example is stronger than that of the first embodiment. Thus, the voltage generation circuit 60 of this example is suitable for the intended purpose in which the tuning characteristics of the resonance frequency are linear.

In this example, as is apparent from FIG. 17, the variation in the control voltage Vc is also relatively large between the state number “22” in which the control voltage Vc is the maximum (3.0 [V]) and the state number “21” immediately before the state number “22”. That is, the variation in the control voltage Vc is relatively large in the vicinity of the maximum value of the control voltage Vc. Accordingly, in this example, the voltage value of a high state of the input port of the voltage generation circuit 60 is also configured to be larger than 3.0 [V] in order to allow the variation in the control voltage Vc to be small in the vicinity of the maximum value of the control voltage Vc as in the third adjustment method described above in the first embodiment.

In this example, as described above, it is possible to increase the number of states of the generable control voltages Vc, compared to the first embodiment, by just changing the connection destination of the output port 30 and varying the resistant value R1 of the first resistor 21 (external resistor). Thus, in this example, the number of states of the necessary control voltages Vc can be designed with a lesser number of input ports. Further, since the voltage generation circuit 60 of this example is provided with no switch therein, the cost can be reduced, as in the above-described first embodiment. Further, the voltage generation circuit 60 can be configured more simply in a space-saving manner.

### Second Modification

In the first embodiment and the first modification described above, for example, one output port is provided, but the present disclosure is not limited thereto. For example, a plurality of output ports may be provided and a predetermined output port may be selected among the plurality of output ports. In a second modification, for example, two output ports are provided.

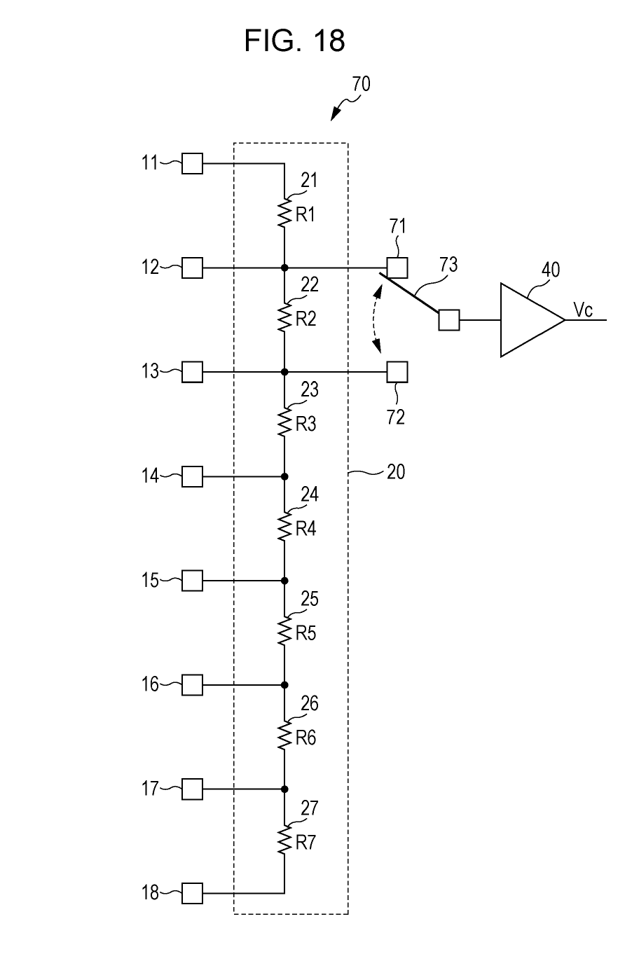

FIG. 18 is a diagram illustrating the overall configuration of a voltage generation circuit according to the second modification. In a voltage generation circuit 70 of the second modification shown in FIG. 18, the same reference numerals are given to the same constituent elements in the same configuration as that of the voltage generation circuit 3 described in FIG. 3 according to the first embodiment.

The voltage generation circuit 70 of this example includes a first input port 11 to an eighth input port 18, a resistor circuit 20, a first output port 71, a second output port 72, and a changeover switch 73 (switch), and an amplifier 40. Since the first input port 11 to the eighth input port 18, the resistor circuit 20, and the amplifier 40 of this example have the same configurations as those of the above-described first embodiment (see FIG. 3), the description of the configurations will not be repeated.

In the voltage generation circuit 70 of this example, the first output port 71 is connected to the second input port 12 and the second output port 72 is connected to the third input port 13. That is, in this example, the first output port 71 and the second output port 72 are connected to the connection point between the first resistor 21 and the second resistor 22 and the connection point between the second resistor 22 and the third resistor 23, respectively.

The changeover switch 73 is installed among the first output port 71, the second output port 72, and the amplifier 40. Further, the changeover switch 73 appropriately selects one of the first output port 71 and the second output port 72 and connects the selected output port to the input terminal of the amplifier 40. A changeover operation of the changeover switch 73 is controlled by, for example, a control unit (not shown) of a contactless type communication apparatus.

In this example, when the changeover switch 73 selects the first output port 71, the voltage generation circuit 70 has the same configuration as that of the voltage generation circuit 3 (see FIG. 3) described above in the first embodiment. On the other hand, when the changeover switch 73 selects the second output port 72, the voltage generation circuit 70 has the same configuration as that of the voltage generation circuit 60 (see FIG. 14) described above in the first modification. Therefore, in this example, the number of states of the generable control voltages Vc can simply be increased by just changing over the output port selected by the changeover switch 73 from the first output port 71 to the second output port 72. That is, in this example, the number of states of the control voltages Vc can be increased more simply with the lesser number of input ports.

In this example, the voltage generation circuit 70 can be simply set to have an optimum configuration, for example, by the tuning characteristics of the necessary resonance frequency. For example, when the voltage generation circuit 70 is used in a case where the tuning characteristics of the nonlinear resonance frequency shown in FIG. 2 is necessary, the changeover switch 73 may select the first output port 71. On the other hand, for example, when the voltage generation circuit 70 is used in a case where the tuning characteristics with high linearity is necessary, the changeover switch 73 may select the second output port 72.

### 2. Second Embodiment

In the first embodiment, as described above, the resistor circuit 20 of the voltage generation circuit 3 is configured such that the plurality of resistors are connected to each other in series, but the present disclosure is not limited thereto. A resistor circuit may be configured such that a plurality of resistors are connected to each other in parallel. In a second embodiment, an exemplary configuration of the resistor circuit will be described. Here, an exemplary configuration in which the number of input ports is eight will be described, as in the above-described first embodiment.

### Configuration of Voltage Generation Circuit

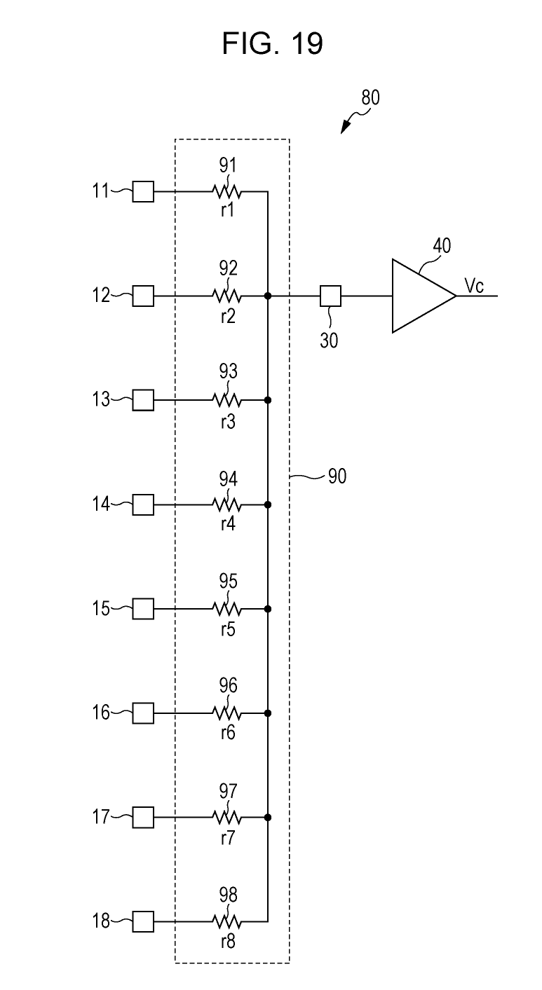

FIG. 19 is a diagram illustrating the overall configuration of the voltage generation circuit according to this embodiment. In a voltage generation circuit 80 according to this embodiment shown in FIG. 19, the same reference numerals are given to the same constituent elements as those of the voltage generation circuit 3 described above in FIG. 3 according to the first embodiment.

A voltage generation circuit 80 includes eight input ports (a first input port 11 to an eighth input port 18), a resistor circuit 90, an output port 30, and an amplifier 40. The first input port 11 to the eighth input port 18, the output port 30, and the amplifier 40 according to this embodiment have the same configurations as those of the above-described first embodiment. That is, the resistor circuit 90 of the voltage generation circuit 80 according to this embodiment has the same configuration as that of the above-described first embodiment. Hereinafter, only the configuration of the resistor circuit 90 will be described.

The resistor circuit 90 includes eight resistors (a first resistor 91 to an eighth resistor 98) such that the resistors are connected to each other in parallel. Specifically, one terminal of the first resistor 91 to one terminal of the eighth resistor 98 are connected to the first input port 11 to the eighth input port, respectively, and all of the other terminals of the first resistor 91 to the eighth resistor 98 are connected to the output port 30. For example, the resistant values (r1 to r8) of the first resistor 91 to the eighth resistor 98 are set appropriately in accordance with the conditions such as the adjustment interval (adjustment steps of the control voltages Vc) of the necessary resonance frequency.

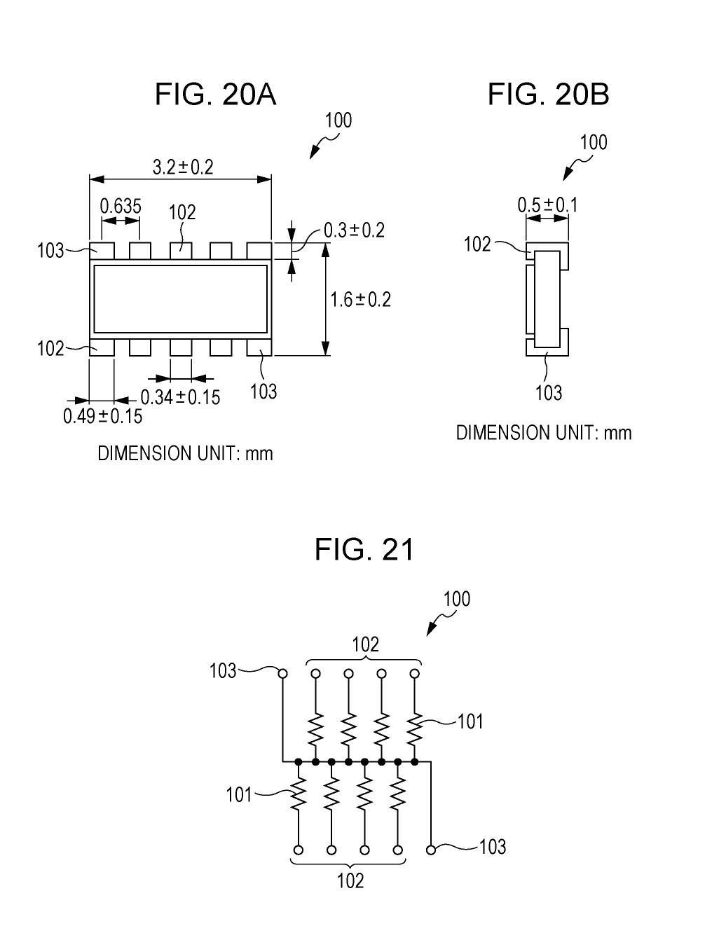

The voltage generation circuit 80 shown in FIG. 19 may be configured by, for example, a commercially available internal connection type (common terminal type) resistor array in which a plurality of resistors are mounted on a substrate. FIGS. 20A and 20B are diagrams illustrating the outer appearance of an internal connection type resistor array applicable to the voltage generation circuit 80 according to this embodiment. FIG. 20A is a top view illustrating the internal connection type resistor array. FIG. 20B is a side view illustrating the internal connection type resistor array viewed from the short side. FIG. 21 is a diagram illustrating an equivalent circuit of the internal connection type resistor array shown in FIGS. 20A and 20B.

An internal connection type resistor array 100 includes eight resistors 101 (resistant elements) separately mounted on a substrate (not shown). One terminal of each resistor 101 of the resistor array 100 is formed as an independent terminal 102 so as to be exposed to the outside. That is, in the resistor array 100 shown in FIGS. 20A, 20B, and 21, eight independent terminals 102 (corresponding to the first input port 11 to the eighth input port 18 in FIG. 19) are exposed to the outside. Further, the other terminals of the respective resistors 101 are electrically connected to each other inside the resistor array 100 and are formed as common terminals 103 so as to be exposed the outside. FIGS. 20A, 20B, and 21 show an example in which the resistor array 100 is provided with two common terminals 103.

The upper surface shape of the resistor array 100 is substantially rectangular and the dimension of the upper surface is a length of 3.2±0 2 mm×a width of 1.6±0.1 mm. The thickness of the resistor array 100 is 0.5 mm±0.1 mm. That is, in this example, the resistor array 100 is smaller in size than the independent type resistor array 50 (see FIGS. 4A and 4B) used in the above-described first embodiment.

In the resistor array 100 shown in FIGS. 20A and 20B, five terminals are exposed in each of a pair of long sides facing each other. The four terminals located at the four corners among the ten terminals exposed to the outside have a dimension of 0.49±0.15 mm×0.3±0.2 mm. The other six terminals have a dimension of 0.34±0.15 mm×0.3±0.2 mm. The terminal pitch of the resistor array 100 shown in FIGS. 20A and 20B is 0.635 mm.

When the internal connection type resistor array 100 shown in FIGS. 20A, 20B, and 21 is applied to the voltage generation circuit 80 according to this embodiment, the eight independent terminals 102 of the resistor array 100 are connected to eight output ports of a CPU, respectively. One of the two common terminals 103 of the resistor array 100 is connected to the output port 30.

### Adjustment Method for Control Voltage

Next, an adjustment method for the control voltage Vc in the voltage generation circuit 80 according to this embodiment will be described. In this embodiment, as in the above-described first embodiment, the control voltage Vc is adjusted by appropriately changing the combinations of the potential states (the high state, the low state, and the open state) of the respective input ports based on control signals input from the CPU to the voltage generation circuit 80.

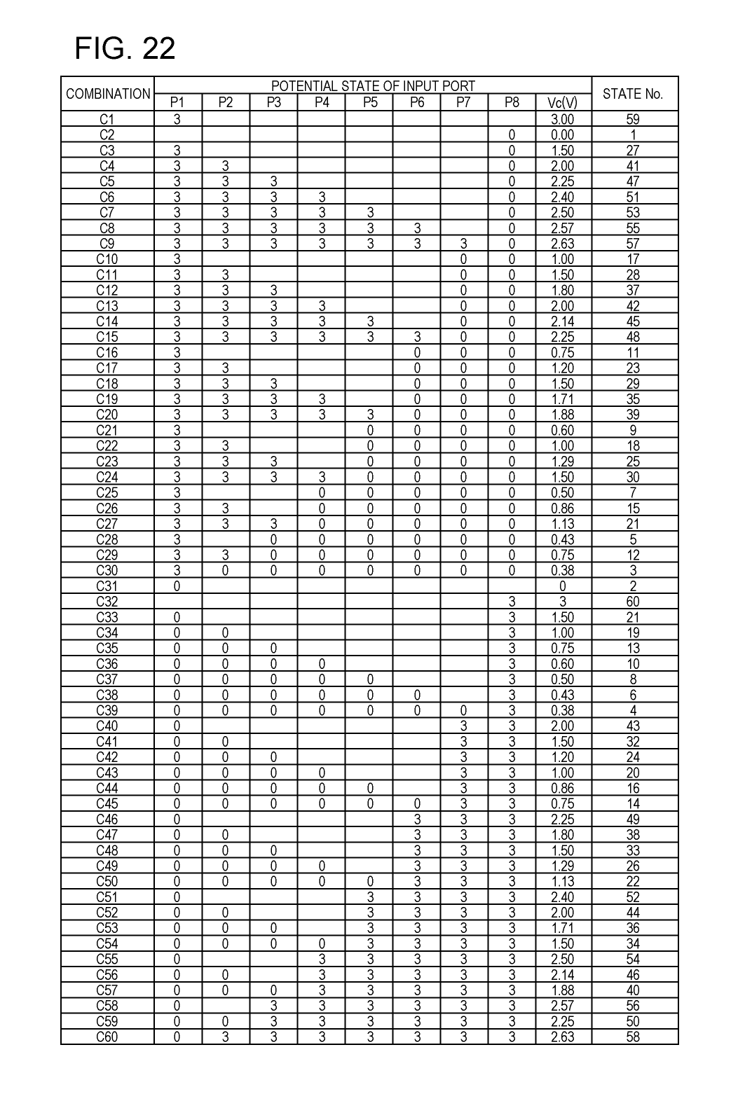

FIG. 22 shows an adjustment table between the combinations of the potential states of the respective input ports (the first input port 11 to the eighth input port 18) and the control voltages Vc output for the combinations. The adjustment table of the control voltage Vc shown in FIG. 22 is an example when the resistant value r1 of the first resistor 91 to the resistant value r8 of the eighth resistor 98 are all the same as each other (1.0 r: reference value). Further, the reference value (1.0 r) of the resistant value is appropriately set in accordance with the conditions such as the intended purpose.

In the voltage generation circuit 80 according to this embodiment, as is apparent from the adjustment table shown in FIG. 22, there are sixty combinations (“C1” to “C60” in FIG. 22) of the potential states of the respective input ports. However, among the sixty combinations, there are various combinations in which the same control voltage Vc is obtained. Therefore, the number of states of the control voltages Vc generated by the voltage generation circuit 80 according to this embodiment is twenty three. Thus, when the resistant values of the first resistor 91 to the eighth resistor 98 are all set to the same value (r1 to r8=1.0 r) in this embodiment, the control voltage Vc can be adjusted by the methods of the twenty three states. That is, in this embodiment, the control voltages Vc can be generated by the number (=23) of states larger than the number (=8) of input ports.

In this embodiment, the resistant values of the first resistor 91 to the eighth resistor 98 can be varied appropriately in accordance with the conditions such as the intended purpose and an adjustment interval (adjustment steps of the control voltage Vc) of the predetermined resonance frequency. For example, the control voltage Vc may also be adjusted by allowing only the resistant value r8 of the eighth resistor 98 to be different from the resistant values (r1 to r8) of the other resistors (the first resistor 91 to the seventh resistor 97).

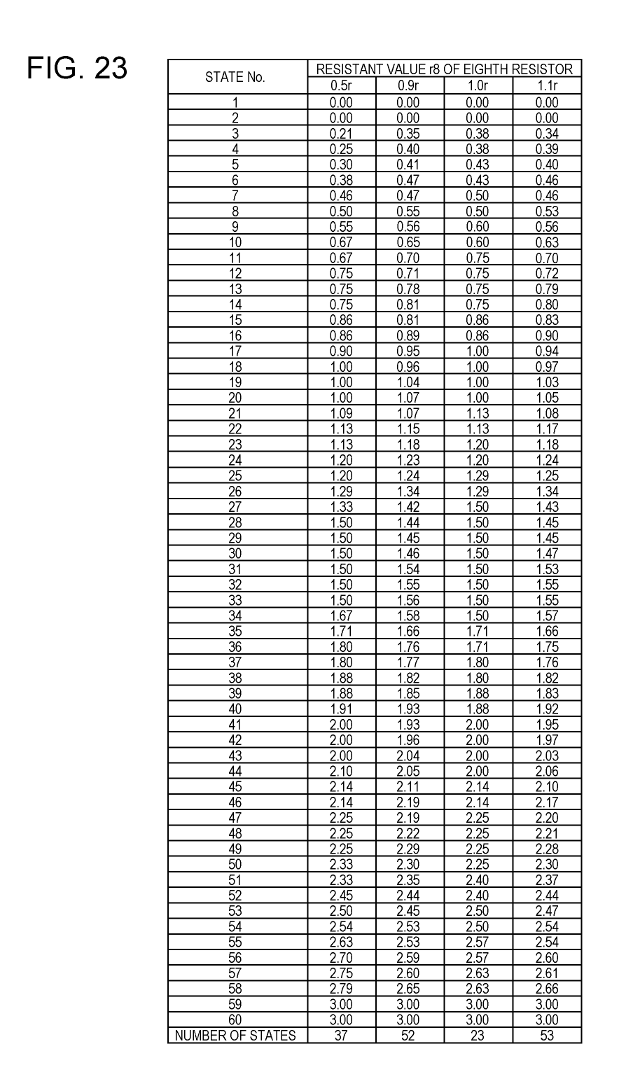

FIG. 23 shows an adjustment table of the control voltages Vc generated by the voltage generation circuit 80 when only the resistant value r8 of the eighth resistor 98 is varied. FIG. 23 shows an example of the adjustment table when the resistant value r1 of the first resistor 91 to the resistant value r7 of the seventh resistor 97 are set to 1.0 r and the resistant value r8 of the eighth resistor 98 is varied to 0.5 r, 0.9 r, 1.0 r, and 1.1 r.

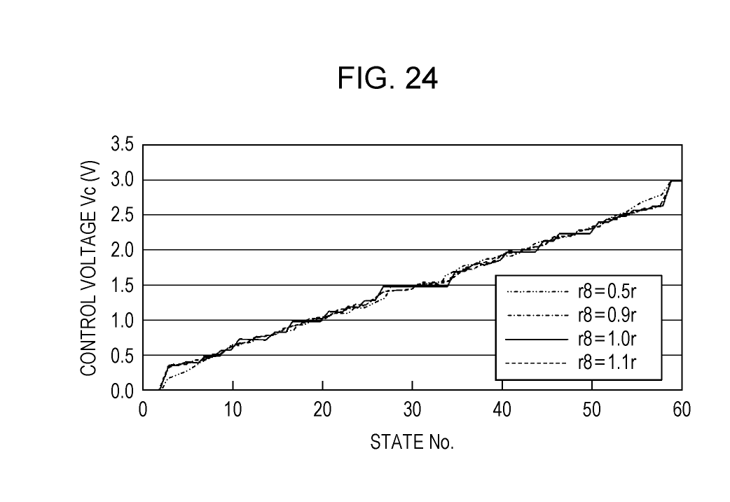

FIG. 24 shows adjustment characteristics (variation characteristics of the control voltages Vc in the state numbers of the control voltages Vc) of the control voltages Vc when the adjustment table shown in FIG. 23 is used. In the adjustment characteristic shown in FIG. 24, the vertical axis represents the control voltage Vc and the horizontal axis represents the state number corresponding to the control voltage Vc. In FIG. 24, graphs indicated by a two-dot chain line, a one-dot chain line, a solid line, and a dashed line show the characteristics when the resistant value r8 of the eighth resistor 98 is set to 0.5 r, 0.9 r, 1.0 r, and 1.1 r, respectively.

As is apparent from FIGS. 23 and 24, the adjustment characteristics of the control voltage Vc are changed for each resistant value r8 of the eighth resistor 98 by varying only the resistant value r8 of the eighth resistor 98. Further, the number of states of the control voltages Vc can be increased up to fifty three by varying only the resistant value r8 of the eighth resistor 98.

In the example shown in FIGS. 23 and 24, the control voltage Vc is adjusted by allowing the resistant value r1 of the first resistor 91 to the resistant value r7 of the seventh resistor 97 to be set to the same value (1.0 r) and varying only the resistant value r8 of the eighth resistor 98. However, only the resistant value r1 of the first resistor 91 may be varied. In this case, it is possible to obtain the adjustment characteristics of the control voltage Vc the number of states of the control voltages Vc as in the case where only the resistant value r8 of the eighth resistor 98 is varied.

In this embodiment, as is apparent from the adjustment characteristics of the control voltage Vc shown in FIG. 24, the variation in the control voltage Vc is relatively large between the state numbers in the vicinity of the maximum value (3.0 [V]) of the control voltage Vc, as in the above-described first embodiment. In this embodiment, therefore, the voltage value V₀ in the high state of the input port may be made to be large and the variation in the control voltage Vc in the vicinity of the maximum value of the control voltage Vc may be made to be small, as in the third adjustment method described above in the first embodiment.

Since the output port 30 is commonly used in the voltage generation circuit 80 according to this embodiment, the number of states of the control voltages Vc may not be increased by changing the connection points between the output port 30 and the resistor circuit 90, as in the first and second modifications described above. In this embodiment, however, as described above, the number of states of the control voltages Vc can be considerably increased by appropriately varying the resistant values of the respective resistors. Thus, the number of states of the control voltages Vc can be increased, compared to the configuration described above in the first embodiment.

In the voltage generation circuit 80 according to this embodiment, as described above, the control voltage Vc can be adjusted and output as in the above-described first embodiment. In this embodiment, it is possible to generate the control voltages Vc of the number of states larger than the number of resistors and the number of input ports (the number of output ports of the CPU connected to the voltage generation circuit 80). Thus, in the voltage generation circuit 80 according to this embodiment, the resonance frequency of the resonance circuit can be adjusted more minutely without increasing the number of resistors and the number of input ports, as in the above-described first embodiment.

As in the above-described first embodiment, since the voltage generation circuit 80 according to this embodiment is provided with no switch therein, the cost can be reduced and the voltage generation circuit 80 can be configured more simply in a space-saving manner.

Further, in the voltage generation circuit 80 according to this embodiment, it is possible to use the commercially available internal connection type resistor array 100 (see FIGS. 20A and 20B) smaller in size than the commercially available independent type resistor array 50 (see FIGS. 4A and 4B) used in the first embodiment. Thus, the configuration of the voltage generation circuit according to this embodiment is superior to the configuration of the voltage generation circuit of the first embodiment in terms of the space-saving.

In the various embodiments and the various modifications, as described above, for example, one of the high state, the low state, the open state of the potential states of the plurality of input ports of the voltage generation circuit is set by the control signal, but the present disclosure is not limited thereto. For example, the potential state of at least one of the plurality of input ports may be set to be fixed to the high state or the low state.

### 3. Various Application Examples

In the various embodiments and the various modifications, as described above, the voltage generation circuit according to the embodiments and modifications of the present disclosure is applied to the resonance circuit unit, but the present disclosure is not limited thereto. The voltage generation circuit according to the embodiments of the present disclosure is applicable to any system or any apparatus (electronic apparatus), as long as the system and apparatus in which it is necessary to adjust the capacitance of variable capacitor (variable capacitance element) by applying a direct-current control voltage to the variable capacitor. Moreover, the same advantages can be obtained. Hereinafter, various application examples (applicable examples) of the voltage generation circuit according to the embodiments of the present disclosure will be described.

### First Application Example: Communication Apparatus

First, in a first application example, an example will be described in which the voltage generation circuit according to the various embodiments and the various modifications is applied to, for example, a communication apparatus such as an information processing terminal having a contactless communication function.

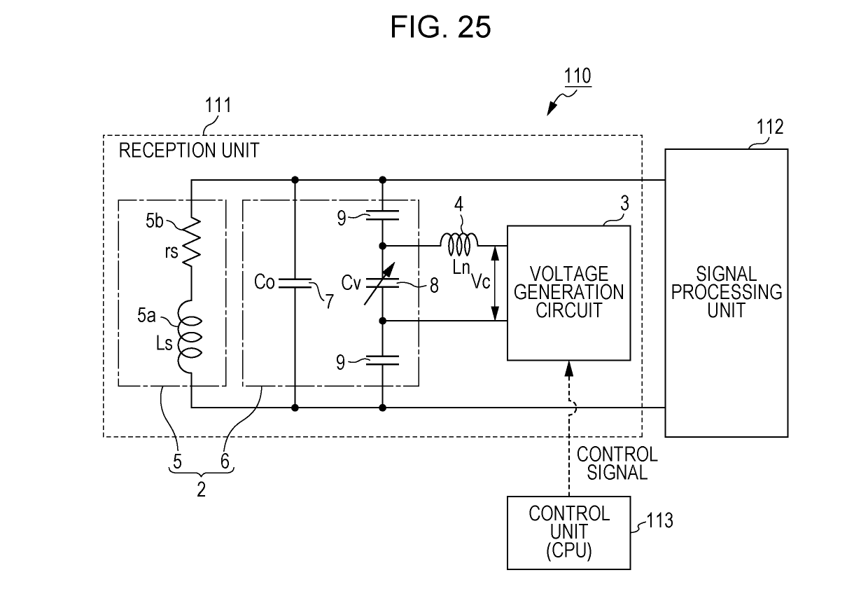

FIG. 25 is a diagram illustrating the overall circuit configuration of a communication apparatus according to the first application example. In a communication apparatus 110 shown in FIG. 25, the same reference numerals are given to the same constituent elements in the configuration of the resonance circuit unit 1 described in FIG. 1 above in the first embodiment. In FIG. 25, in order to facilitate the description, only the configuration of the circuit unit of the reception system (demodulation system) of the communication apparatus 110 is illustrated. The other configuration including a circuit unit of a signal transmission system (modulation system) is the same as that of a communication apparatus according to the related art.

The communication apparatus 110 includes a reception unit 111, a signal processing unit 112, and a control unit 113.

The reception unit 111 includes a resonance antenna 2 (a reception antenna unit and a communication unit), a voltage generation circuit 3 applying a direct-current control voltage Vc to the resonance antenna 2, and a coil 4. In this example, the reception unit 111 has the same configuration as that of the resonance circuit unit 1 described above in the first embodiment. For example, the reception unit 111 receives a signal from an external R/W device (not shown) by contactless communication through the resonance antenna 2 and outputs the received signal to the signal processing unit 112. In this example, any one of the voltage generation circuits described in the various embodiments and the various modifications is applied to the voltage generation circuit 3.

The signal processing unit 112 performs predetermined processing on the AC signal received by the reception unit 111 to modulate the alternating-current signal.

The control unit 113 is configured by a circuit such as a CPU (Central Processing Unit) controlling the general operations of the communication apparatus 110. A plurality of output ports (I/O ports) of the CPU (the control unit 113) are connected to the plurality of corresponding input ports of the voltage generation circuit 3, respectively.

In this example, as in the various embodiments and the various modifications, the combinations of the potential states (the high state, the low state, and the open state) of the respective input ports are appropriately changed based on the control signals input from the CPU (the control unit 113) to the respective input ports of the voltage generation circuit 3. In this way, the resonance frequency of the reception unit 111 (the resonance antenna 2) is adjusted by adjusting the control voltage Vc applied to the variable capacitor 8.

As described above, since the voltage generation circuit described above the various embodiments and the various modifications is used in the communication apparatus 110 of this example, the cost can be reduced and the configuration is realized more simply in a space-saving manner.

### Second Application Example: Communication System

Next, an example (second application example) will be described in which the voltage generation circuit according to the various embodiments and the various modifications is applied to a communication system transmitting and receiving information in contactless communication.

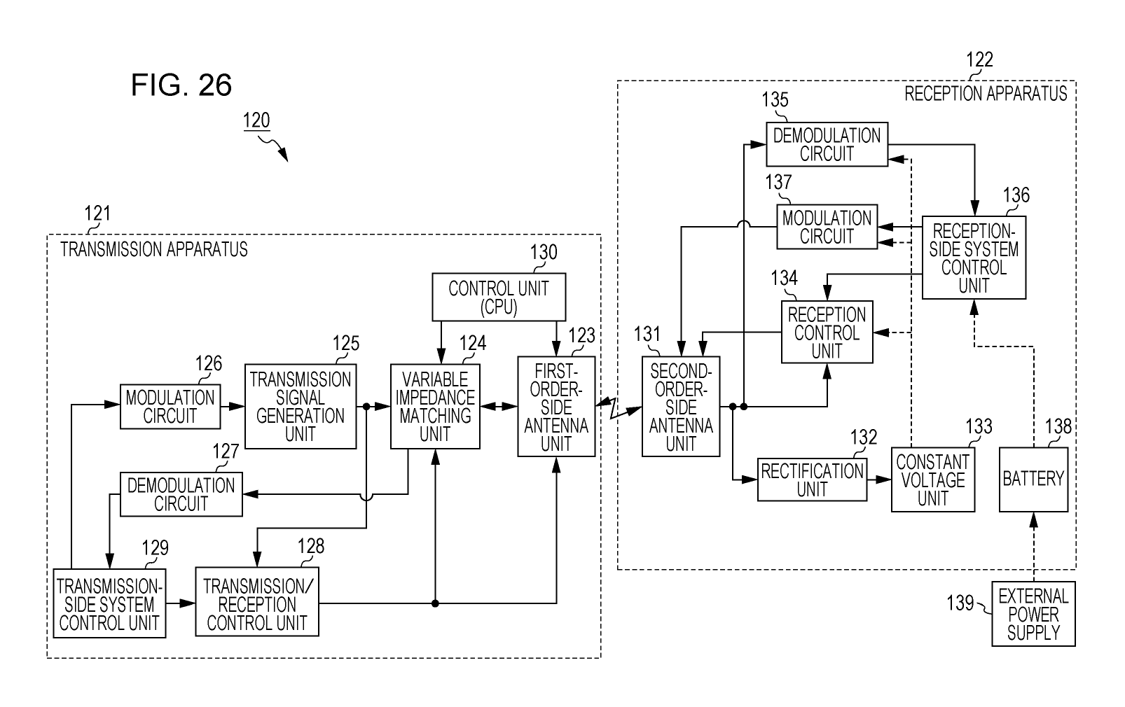

FIG. 26 is a diagram illustrating the overall configuration of the communication system according to the second application example. FIG. 26 shows only the configurations of the main units associated with the contactless communication are shown to facilitate the description. In FIG. 26, a wiring used to input and output information between the circuit blocks is indicated by a solid line and a wiring used to supply power is indicated by a dotted line.

A communication system 120 includes a transmission apparatus 121 and a reception apparatus 122. In the communication system 120, information is transmitted and received by contactless communication between the transmission apparatus 121 and the reception apparatus 122. An example of the communication system 120 with the configuration shown in FIG. 26 is a communication system, such as FeliCa (registered trademark) as a representative example, in which a contactless type IC card standard and a near field communication (NFC) standard are combined. Hereinafter, the configuration of each apparatus will be described in more detail.

### (1) Transmission Apparatus

The transmission apparatus 121 is an apparatus that has reader and writer functions of reading and writing data from and in the reception apparatus 122 in a contactless manner. The transmission apparatus 121 includes a primary side antenna unit (transmission antenna unit) 123, a variable impedance matching unit 124, a transmission signal generation unit 125, a modulation circuit 126, a demodulation circuit 127, a transmission/reception control unit 128, and a transmission-side system control unit 129. The transmission unit 121 further includes a control unit 130 controlling the general operations of the transmission apparatus 121.

An electric connection relationship between the respective units of the transmission apparatus 121 is as follows. That is, the primary side antenna unit 123 is connected to the variable impedance matching unit 124, and inputs and outputs signals. One control terminal and the other control terminal of the primary side antenna unit 123 are connected to the transmission/reception control unit 128 and the control unit 130, respectively. The input terminal of the variable impedance matching unit 124 is connected to the output terminal of the transmission signal generation unit 125. The output terminal of the variable impedance matching unit 124 is connected to the input terminal of the demodulation circuit 127. One control terminal and the other control terminal of the variable impedance matching unit 124 are connected to the transmission/reception control unit 128 and the control unit 130, respectively.

The input terminal of the transmission signal generation unit 125 is connected to the output terminal of the modulation circuit 126. The input terminal of the modulation circuit 126 is connected to one output terminal of the transmission-side system control unit 129. The output terminal of the demodulation circuit 127 is connected to the input terminal of the transmission-side system control unit 129. One input terminal and the other input terminal of the transmission/reception control unit 128 are connected to the output terminal of the transmission signal generation unit 125 and the other output terminal of the transmission-side system control unit 129, respectively.

Next, the configuration and function of each unit of the transmission apparatus 121 will be described. The primary side antenna unit 123 has the same configuration as that of the resonance circuit unit 1 (see FIG. 1) described above in the first embodiment. The primary side antenna unit 123 includes a resonance circuit including a resonance coil and a resonance capacitor and a voltage generation circuit adjusting the capacitance of the resonance capacitor. The primary side antenna unit 123 allows the resonance circuit to transmit a transmission signal with a desired frequency and receives a response signal from the reception apparatus 122 described below. At this time, the voltage generation circuit adjusts the capacitance of the resonance capacitor so that the resonance frequency of the resonance circuit is the desired frequency. In this example, any one of the voltage generation circuit according to the various embodiments and the various modifications described above is applied to the voltage generation circuit of the primary side antenna unit 123.

The variable impedance matching unit 124 is a circuit that matches impedance between the transmission signal generation unit 125 and the primary side antenna unit 123. Although not illustrated in FIG. 26, the variable impedance matching unit 124 includes a variable capacitor and a voltage generation circuit adjusting the capacitance of the variable capacitor. In this example, the impedance between the transmission signal generation unit 125 and the primary side antenna unit 123 is matched by allowing the voltage generation circuit to adjust the capacitance of the variable capacitor. In this example, any one of the voltage generation circuit according to the various embodiments and the various modifications described above is applied to the voltage generation circuit of the variable impedance matching unit 124.

The transmission signal generation unit 125 modulates a carrier signal with a desired frequency (for example, 13.56 MHz) based on transmission data input from the modulation circuit 126 and outputs the modulated carrier signal to the primary side antenna unit 123 via the variable impedance matching unit 124.

The modulation circuit 126 modulates transmission data input from the transmission-side system control unit 129 and outputs the modulated transmission data to the transmission signal generation unit 125.

The demodulation circuit 127 acquires a response signal received by the primary side antenna unit 123 via the variable impedance matching unit 124 and demodulates the response signal. Then, the demodulation circuit 127 outputs the demodulated response data to the transmission-side system control unit 129.

The transmission/reception control unit 128 monitors communication states such as a transmission voltage and a transmission current of the carrier signal transmitted from the transmission signal generation unit 125 to the variable impedance matching unit 124. Then, the transmission/reception control unit 128 outputs a control signal to the variable impedance matching unit 124 and the primary side antenna unit 123 based on the monitoring result of the communication states.

The transmission-side system control unit 129 generates control signals used for various controls in accordance with an instruction from the outside or an included program, outputs the control signals to the modulation circuit 126 and the transmission/reception control unit 128, and controls the operations of both the modulation circuit 126 and the transmission/reception control unit 128. The transmission-side system control unit 129 generates transmission data corresponding to the control signals (instruction signals) and supplies the transmission data to the modulation circuit 126. Further, the transmission-side system control unit 129 performs a predetermined process based on the response data demodulated by the demodulation circuit 127.

The control unit 130 is configured by a circuit such as a CPU. A plurality of output ports (I/O ports) of the CPU (the control unit 130) are connected to the plurality of input ports corresponding to the voltage generation circuits of the primary side antenna unit 123 and the variable impedance matching unit 124, respectively. Further, the control unit 130 appropriately changes the combinations of the potential states (the high state, the low state, and the open states) of the respective input ports based on the control signals input from the transmission/reception control unit 128 to the primary side antenna unit 123 and the variable impedance matching unit 124. In this way, the control unit 130 controls the control voltages applied to the variable capacitors of the primary side antenna unit 123 and the variable impedance matching unit 124. At this time, the control unit 130 controls the control voltages to optimize the matching of the impedance between the transmission signal generation unit 125 and the primary side antenna unit 123 the resonance frequency of the primary side antenna unit 123.

In the example shown in FIG. 26, as described above, the transmission/reception control unit 128, the transmission-side system control unit 129, and the control unit 130 (CPU) are independently installed in the transmission apparatus 121, but the present disclosure is not limited thereto. The control unit 130 may include the transmission/reception control unit 128 and the transmission-side system control unit 129.

### (2) Reception Apparatus

Next, the reception apparatus 122 will be described. In the example shown in FIG. 26, the reception apparatus 122 is configured by a contactless type IC card (data carrier). In this example, an example will be described in which the reception apparatus 122 has a function of adjusting the resonance frequency of the reception apparatus 122.

The reception apparatus 122 includes a secondary side antenna unit (reception antenna unit) 131, a rectification unit 132, a constant voltage unit 133, a reception control unit 134, a demodulation circuit 135, a reception-side system control unit 136, a modulation circuit 137, and a battery 138.

An electric connection relationship between the respective units of the reception apparatus 122 is as follows. That is, the output terminal of the secondary side antenna unit 131 is connected to the input terminal of the rectification unit 132, one input terminal of the reception control unit 134, and the input terminal of the demodulation circuit 135. Further, the input terminal of the secondary side antenna unit 131 is connected to the output terminal of the modulation circuit 137 and the control terminal of the secondary side antenna unit 131 is connected to the output terminal of the reception control unit 134. The output terminal of the rectification unit 132 is connected to the input terminal of the constant voltage unit 133. Furthermore, the output terminal of the constant voltage unit 133 is connected to the power input terminals of the reception control unit 134, the modulation circuit 137, and the demodulation circuit 135.

The other input terminal of the reception control unit 134 is connected to one output terminal of the reception-side system control unit 136. The output terminal of the demodulation circuit 135 is connected to the input terminal of the reception-side system control unit 136. Further, the input terminal of the modulation circuit 137 is connected to the other output terminal of the reception-side system control unit 136. Furthermore, the power input terminal of the reception-side system control unit 136 is connected to the output terminal of the battery 138.

Next, the configuration and function of each unit of the reception apparatus 122 will be described. Although not illustrated in the drawing, the secondary side antenna unit 131 includes a resonance circuit including a resonance coil and a resonance capacitor. The resonance capacitor includes a variable capacitor of which capacitance is varied by applying a control voltage. The secondary side antenna unit 131 is a unit that communicates with the transmission apparatus 121 (the primary side antenna unit 123) by electromagnetic coupling. The secondary side antenna unit 131 receives a magnetic field generated by the primary side antenna unit 123 and receives the signal transmitted from the transmission apparatus 121. At this time, the capacitance of the variable capacitor is adjusted so that the resonance frequency of the secondary side antenna unit 131 becomes a desired frequency.

The rectification unit 132 is configured by, for example, a half-wave rectifier circuit including a rectifying diode and a rectifying capacitor. The rectification unit 132 rectifies an alternating-current power received by the secondary side antenna unit 131 to a direct-current power and outputs the rectified direct-current power to the constant voltage unit 133.

The constant voltage unit 133 performs voltage variation (data component) suppressing operation and stabilizing operations on an electric signal (direct-current power) input from the rectification unit 132 and supplies the processed direct-current power to the reception control unit 134. The direct-current power output via the rectification unit 132 and the constant voltage unit 133 are used as power for operating an IC in the reception apparatus 122.

The reception control unit 134 is configured by, for example, an IC and monitors the size, the phase of voltage/current, or the like of a reception signal received by the secondary side antenna unit 131. Further, the reception control unit 134 controls the resonance characteristics of the secondary side antenna unit 131 based on the monitoring result of the reception signal and optimizes the resonance frequency at the reception time. Specifically, the reception control unit 134 applies a control voltage to the variable capacitor of the secondary side antenna unit 131 and adjusts the capacitance of the variable capacitor to consequently adjust the resonance frequency of the secondary side antenna unit 131.

The demodulation circuit 135 demodulates the reception signal received by the secondary side antenna unit 131 and outputs the demodulated signal to the reception-side system control unit 136.

The reception-side system control unit 136 performs processing necessary for determining the details of the signal demodulated by the demodulation circuit 135 based on this signal and controls the modulation circuit 137 and the reception control unit 134.

The modulation circuit 137 modulates a received carrier in accordance with the result (the details of the demodulated signal) determined by the reception-side system control unit 136 and generates a response signal. Then, the modulation circuit 137 outputs the generated response signal to the secondary side antenna unit 131. The response signal output from the modulation circuit 137 is transmitted from the secondary side antenna unit 131 to the primary side antenna unit 123 by contactless communication.

The battery 138 supplies power to the reception-side system control unit 136. The battery 138 is charged when the charging terminal of the battery 138 is connected to an external power supply 139. Like this example, when the reception apparatus 122 has the battery 138 therein, the power can be supplied to the reception-side system control unit 136 more reliably, thereby realizing a reliable operation. In this example, a direct-current power generated via the rectification unit 132 and the constant voltage unit 133 without using the battery 138 may be used to drive the reception-side system control unit 136.

In the communication system 120 with the above-described configuration, the contactless data communication is realized by the electromagnetic coupling between the primary side antenna unit 123 of the transmission apparatus 121 and the secondary side antenna unit 131 of the reception apparatus 122. Accordingly, in order to realize the communication between the transmission apparatus 121 and the reception apparatus 122 more efficiently, the resonance circuits of the primary side antenna unit 123 and the secondary side antenna unit 131 are configured to resonate at the same carrier frequency (in this embodiment, 13.56 MHz).

In this example, the capacitances of the variable capacitors of the primary side antenna unit 123 and the variable impedance matching unit 124 are adjusted by one of the voltage generation circuits described above in the various embodiments and the various modifications. Thus, in the communication system 120 of this example, since both the resonance frequency and the impedance matching characteristics can optimally be retained, thereby improving the communication characteristics.

In the transmission apparatus 121 of this example, as described above, the voltage generation circuit described above in the various embodiments and the various modifications is used. Accordingly, the transmission apparatus having the function of adjusting the resonance frequency is configured at lower cost and more simply in a space-saving manner.

In this example, as described above, the reception apparatus 122 is configured by a contactless type IC card (data carrier), but the present disclosure is not limited thereto. The communication apparatus, such as an information processing terminal having a contactless communication function, described above in the first application example may be used as the reception apparatus 122. For example, when the contactless type IC card (data carrier) includes a CPU having the same performance as that of a system CPU mounted on the communication apparatus such as an information processing terminal having a contactless communication function, any voltage generation circuit according to the embodiments and the modifications of the present disclosure is applicable to the contactless type IC card.

In this case, the resonance frequencies of the primary side antenna unit 123 and the secondary side antenna unit 131 can independently be adjusted by any voltage generation circuit described above in the various embodiments and the various modifications. Accordingly, even when the received resonance frequency and/or the transmitted resonance frequency are deviated due to various causes, the deviation in each resonance frequency can easily be adjusted in each apparatus of the communication system 120 with the above-described configuration, thereby obtaining the reliable communication characteristics.

### Third Application Example: Wireless Charging System

Next, an example (third application example) will be described in which any voltage generation circuit described above in the various embodiments and the various modifications is applied to a wireless charging system transmitting and receiving (transferring) power by contactless communication.

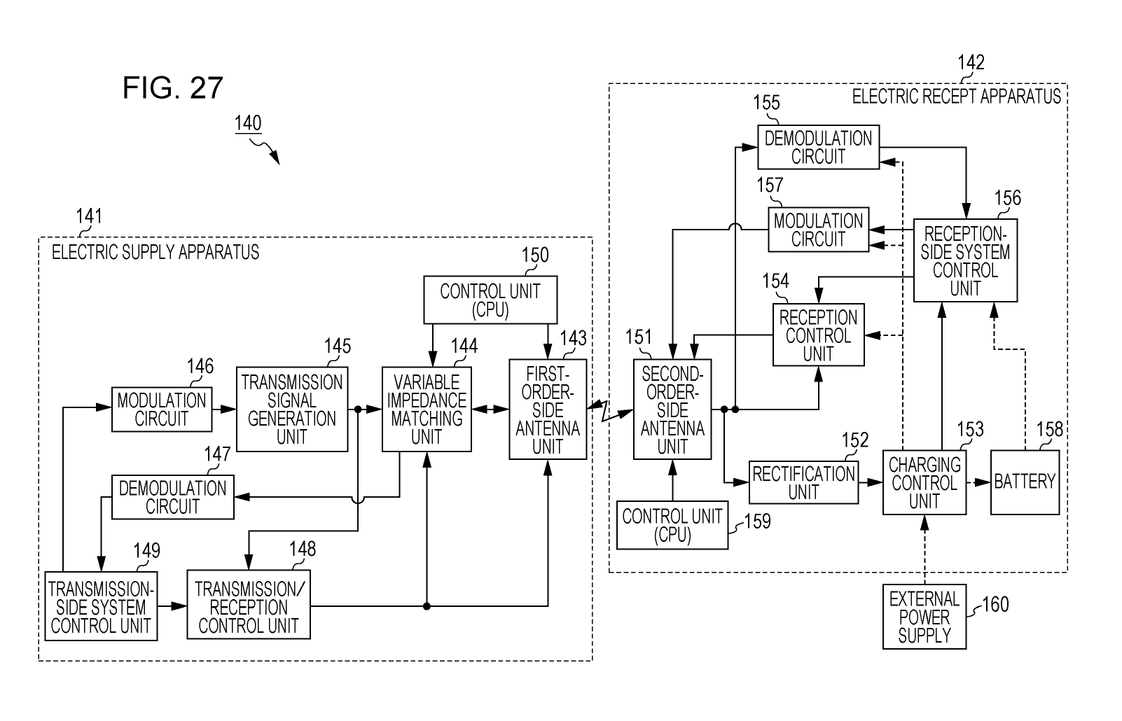

FIG. 27 is a block diagram illustrating the overall configuration of the wireless charging system according to the third application example. FIG. 27 shows only the configurations of the main units associated with the contactless communication are shown to facilitate the description. In FIG. 27, a wiring used to input and output information between the circuit blocks is indicated by a solid line and a wiring used to supply power is indicated by a dotted line.

A wireless charging system 140 includes a power feeding apparatus 141 (power feeding apparatus unit) and a power receiving apparatus 142 (power receiving apparatus unit). In the wireless charging system 140, power is transmitted and received (transferred) between the power feeding apparatus 141 and the power receiving apparatus 142 by the contactless communication. In the wireless charging system 140 of this example, a scheme such as electromagnetic induction or magnetic-field resonance is applied as a charging scheme for power feeding (charging) in a contactless manner. Hereinafter, the configuration of each apparatus will be described in more detail.

### (1) Power Feeding Apparatus

The power feeding apparatus 141 is an apparatus that feeds power to a desired electronic apparatus (the power reception apparatus 142) in a contactless manner. The power feeding apparatus 141 includes a primary side antenna unit (power-feeding antenna unit) 143, a variable impedance matching unit 144, a transmission signal generation unit 145, a modulation circuit 146, a demodulation circuit 147, a transmission/reception control unit 148, a transmission-side system control unit 149, and a control unit 150.

The primary side antenna unit 143 and the variable impedance matching unit 144 of the power feeding apparatus 141 have the same configurations as those of the primary side antenna unit 123 and the variable impedance matching unit 124 of the transmission apparatus 121 described above in the second application example. That is, in this example, any one of the voltage generation circuits described above in the various embodiments and the various modifications is installed in each of the primary side antenna unit 143 and the variable impedance matching unit 144 of the power feeding apparatus 141.

Further, the transmission signal generation unit 145, the modulation circuit 146, and the demodulation circuit 147 of the power feeding apparatus 141 have the same configurations as those of the transmission signal generation unit 125, the modulation circuit 126, and the demodulation circuit 127 of the transmission apparatus 121 described above in the second application example. Furthermore, the transmission/reception control unit 148, the transmission-side system control unit 149, and the control unit 150 of the power feeding apparatus 141 have the same configurations as those of the transmission/reception control unit 128, the transmission-side system control unit 129, and the control unit 130 of the transmission apparatus 121 described above in the second application example. The electric connection relationship of each unit of the power feeding apparatus 141 is the same as that of each unit of the transmission apparatus 121 described in the second application example.

In the example shown in FIG. 27, as described above, the transmission/reception control unit 148, the transmission-side system control unit 149, and the control unit 150 (CPU) are independently installed in the power feeding apparatus 141, but the present disclosure is not limited thereto. The control unit 150 may include transmission/reception control unit 148 and the transmission-side system control unit 149.

### (2) Power Reception Apparatus

The power receiving apparatus 142 is configured by, for example, an apparatus such as a portable apparatus having a contactless communication function. The power receiving apparatus 142 includes a secondary side antenna unit (power receiving antenna unit) 151, a rectification unit 152, a charging control unit 153, a reception control unit 154, a demodulation circuit 155, a reception-side system control unit 156, a modulation circuit 157, a battery 158, and a control unit 159.

An electric connection relationship between the respective units of the power receiving apparatus 142 is as follows. That is, the output terminal of the secondary side antenna unit 151 is connected to the input terminal of the rectification unit 152, one input terminal of the reception control unit 154, and the input terminal of the demodulation circuit 155. Further, the input terminal of the secondary side antenna unit 151 is connected to the output terminal of the modulation circuit 157. Furthermore, one control terminal and the other control terminal of the secondary side antenna unit 151 are connected to the output terminal of the reception control unit 154 and the output terminal of the control unit 159.

The output terminal of the rectification unit 152 is connected to the input terminal of the charging control unit 153. The output terminal of the charging control unit 153 is connected to one input terminal of the reception-side system control unit 156. One power output terminal of the charging control unit 153 is connected to the power input terminals of the reception control unit 154, the modulation circuit 157, and the demodulation circuit 155. The other power output terminal of the charging control unit 153 is connected to the charging terminal of the battery 158. The other input terminal of the reception control unit 154 is connected to one output terminal of the reception-side system control unit 156. The output terminal of the demodulation circuit 155 is connected to the other input terminal of the reception-side system control unit 156. The input terminal of the modulation circuit 157 is connected to the other output terminal of the reception-side system control unit 156. The power input terminal of the reception-side system control unit 156 is connected to the output terminal of the battery 158.

Next, the configuration and function of each unit of the power receiving apparatus 142 will be described. In this example, the configuration of each unit other than the secondary side antenna unit 151, the charging control unit 153, and the control unit 159 is the same as that of each unit of the reception apparatus 122 of the communication system 120 described above in the second application example. Therefore, only the configurations of the secondary side antenna unit 151, the charging control unit 153, and the control unit 159 will be described below.

The secondary side antenna unit 151 has the same configuration as that of the resonance circuit unit 1 described above in the first embodiment. That is, the secondary side antenna unit 151 includes a resonance circuit including a resonance coil and a resonance capacitor and a voltage generation circuit adjusting the capacitance of the resonance capacitor. The secondary side antenna unit 151 is an antenna unit that transmits power by the power feeding apparatus 141 (the primary side antenna unit 143) and electromagnetic coupling. The secondary side antenna unit 151 receives a magnetic field generated by the primary side antenna unit 143 and receives the power transmitted from the power feeding apparatus 141. At this time, the capacitance of the variable capacitor is adjusted so that the resonance frequency of the secondary side antenna unit 151 becomes a desired frequency by applying the control voltage controlled by the voltage generation circuit to the variable capacitor. Further, the operation control (control of the control voltage) of the voltage generation circuit is performed based on a control signal input from the control unit 159.

The charging control unit 153 supplies the battery 158 with an electric signal (direct-current power) input from the rectification unit 152 to charge the battery 158 with the supplied electric signal and also supplies the electric signal as a driving power of the reception control unit 154 to the reception control unit 154. Further, the charging control unit 153 monitors the charging status and outputs the monitoring result to the reception-side system control unit 156. Furthermore, the charging control unit 153 can be connected to an external power supply 160. When the charging control unit 153 is connected to the external power supply 160, the power output from the external power supply 160 is supplied to the battery 158 via the charging control unit 153 so as to charge the battery 158. Further, when the battery 158 is charged by the external power supply 160, the external power supply 160 may be connected directly to the battery 158.

The control unit 159 is configured by, for example, a circuit such as a CPU. A plurality of output ports (I/O ports) of the CPU (the control unit 159) are connected to a plurality of corresponding input ports of the voltage generation circuit of the secondary side antenna unit 151. Further, the control unit 159 appropriately changes the combinations of the potential states (the high state, the low state, and the open states) of the respective input ports based on the control signals input from the reception control unit 154 to the secondary side antenna unit 151. In this way, the control unit 159 adjusts the control voltages applied to the variable capacitor of the secondary side antenna unit 151. At this time, the control unit 159 adjusts the control voltages to optimize the resonance frequency of the secondary side antenna unit 151.

In the example shown in FIG. 27, as described above, the reception control unit 154, the reception-side system control unit 156, and the control unit 159 (CPU) are independently installed in the power receiving apparatus 142, but the present disclosure is not limited thereto. The control unit 159 may include the reception control unit 154 and the reception-side system control unit 156.

In the wireless charging system 140 with the above-described configuration, electromagnetic waves for transmitting the power are transmitted from the primary side antenna unit 143 based on the signal output from the transmission-side system control unit 149 of the power feeding apparatus 141, and then the electromagnetic waves are received by the secondary side antenna unit 151 of the power receiving apparatus 142. The signal received by the secondary side antenna unit 151 is converted into the direct-current power by the rectification unit 152 and the battery 158 is charged with the direct-current power via the charging control unit 153.

In the wireless charging system 140 of this example, the signal received by the secondary side antenna unit 151 of the power receiving apparatus 142 is demodulated by the demodulation circuit 155. Subsequently, the reception-side system control unit 156 determines the details of the demodulated data. The modulation circuit 157 modulates the received carrier signal depending on the determination result. Then, the modulation circuit 157 transmits the modulated received carrier signal as a response signal to the power feeding apparatus 141 via the secondary side antenna unit 151.

By the series of recognition processes, it is possible to prevent the power from being transmitted to an apparatus of another method or a metal. When it is determined that the power is transmitted correctly in the recognition process, the transmission signal is output without being modulated in order to transmit the power. At this time, safety is ensured by intermittently performing the recognition process in order to perform the charging for a long time.

In the wireless charging system 140 of this example, as described above, the charging status is monitored by the charging control unit 153 of the power receiving apparatus 142. In order to obtain an optimum charging status, information regarding the charging status is transmitted to the power feeding apparatus 141 via the reception-side system control unit 156, the modulation circuit 157, and the secondary side antenna unit 151. On the other hand, the information regarding the charging status replied from the power receiving apparatus 142 is demodulated by the demodulation circuit 147 of the power feeding apparatus 141, and the details of the demodulated data are determined by the transmission-side system control unit 149. Then, transmission-side system control unit 149 appropriately performs the necessary processing based on the determination result.

In the operation of the above-described wireless charging system 140, the resonance frequency of the variable impedance matching unit 144, the primary side antenna unit 143, and the secondary side antenna unit 151 is appropriately adjusted by the voltage generation circuit of each unit. Thus, even when the received resonance frequency and/or the transmitted resonance frequency are deviated due to various causes, the deviation in each resonance frequency can easily be adjusted in each apparatus of the wireless charging system 140 with the above-described configuration, thereby reliably realizing the operation of transmitting the power.

Fourth Application Example: Power Supply apparatus

Next, an example (fourth application example) will be described in which any voltage generation circuit described above in the various embodiments and the various modifications is applied to a power supply apparatus.

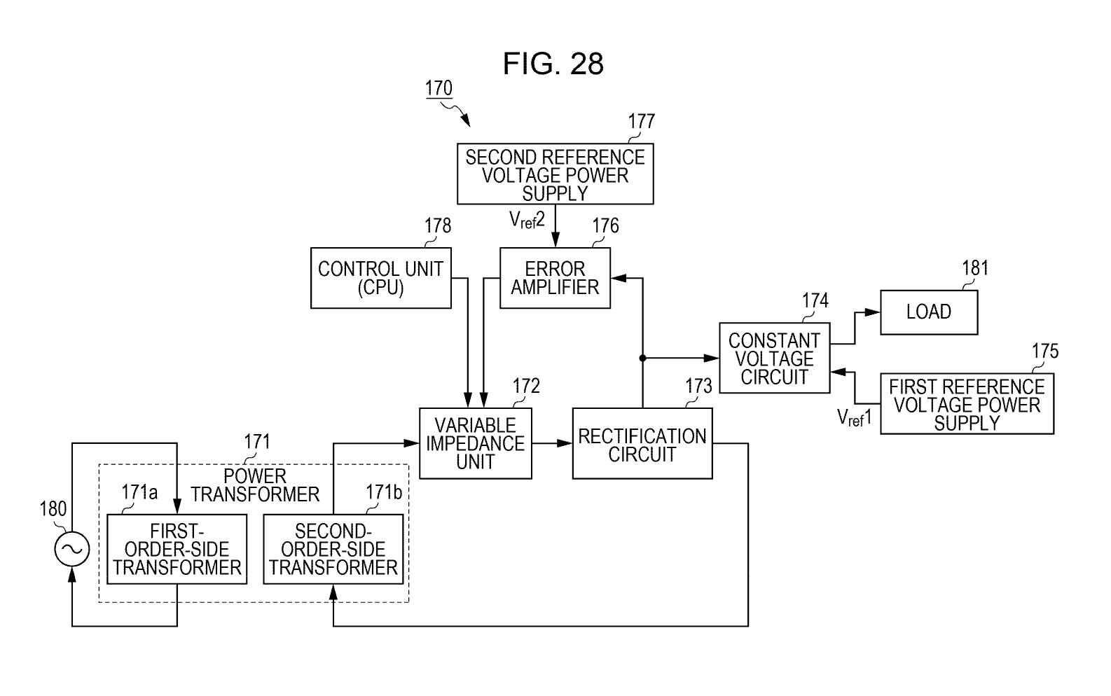

FIG. 28 is a block diagram illustrating the overall configuration of the power supply apparatus according to the fourth application example. Hereinafter, a power supply apparatus 170 dropping the voltage (AC 100 V) of a commercial power supply 180 via a power supply transformer 171 will be described as an example.

The power supply apparatus 170 includes the power supply transformer 171 (power supply unit), a variable impedance unit 172, a rectification circuit 173 (rectification circuit unit), a constant voltage circuit 174, a first reference voltage power supply 175, an error amplifier 176, a second reference voltage power supply 177, and a control unit 178.

An electric connection relationship between the respective units of the power supply apparatus 170 is as follows. In the power supply transformer 171, a primary side transformer 171a described below is connected to the commercial power supply 180, as shown in FIG. 28. In the power supply transformer 171, on the other hand, the output terminal of a secondary side transformer 171b described below is connected to the input terminal of the variable impedance unit 172 and the input terminal of the secondary side transformer 171b is connected to one output terminal of the rectification circuit 173.

The output terminal of the variable impedance unit 172 is connected to the input terminal of the rectification circuit 173. One control terminal of the variable impedance unit 172 is connected to the output terminal of the error amplifier 176. The other control terminal of the variable impedance unit 172 is connected to the control unit 178. The other output terminal of the rectification circuit 173 is connected to one input terminal of the constant voltage circuit 174 and one input terminal of the error amplifier 176.

As shown in FIG. 28, the other input terminal of the constant voltage circuit 174 is connected to the first reference voltage power supply 175 and the output terminal of the constant voltage circuit 174 is connected to a load 181. Further, the other input terminal of the error amplifier 176 is connected to the second reference voltage power supply 177.

Next, the configuration and function of each unit of the power supply apparatus 170 will be described. As shown in FIG. 28, the power supply transformer 171 includes the primary side transformer 171a and the secondary side transformer 171b. The power supply transformer 171 drops the voltage of the commercial power supply 180 at a ratio corresponding to the winding number between the primary side transformer 171a and the secondary side transformer 171b and outputs the dropped voltage to the variable impedance unit 172.

Although not illustrated in FIG. 28, the variable impedance unit 172 includes a variable capacitor and a voltage generation circuit adjusting the capacitance of the variable capacitor. In this example, any one of the voltage generation circuits described above in the various embodiments and the various modifications is applied to the voltage generation circuit of the variable impedance unit 172.

The variable impedance unit 172 varies the impedance by increasing and decreasing the capacitance of the variable capacitor. In this way, the variable impedance unit 172 increases or decreases an alternating-current voltage input from the secondary side transformer 171b and supplies the increased or decreased alternating-current voltage to the rectification circuit 173.

The rectification circuit 173 is configured by, for example, a half-wave rectifier circuit including a rectifying diode and a rectifying capacitor. The rectification circuit 173 converts the alternating-current voltage input from the variable impedance unit 172 into a direct-current voltage and supplies the direct-current voltage to the constant voltage circuit 174 and the error amplifier 176.

The constant voltage circuit 174 compares the direct-current voltage input from the rectification circuit 173 to a reference voltage V_{ref}1 supplied from the first reference voltage power supply 175, generates a direct-current voltage with a constant voltage value, and supplies the direct-current voltage with the constant voltage value to the load 181. Specifically, the constant voltage circuit 174 increases or decreases the voltage decrease amount of an input voltage in the constant voltage circuit 174 so that the voltage applied to the load 181 is equal to the reference voltage V_{ref}1.

The error amplifier 176 compares the direct-current voltage input from the rectification circuit 173 to a reference voltage V_{ref}2 supplied from the second reference voltage power supply 177 and controls the impedance of the variable impedance unit 172 based on the comparison result. The reference voltage V_{ref}2 output from the second reference voltage power supply 177 is set to be slightly higher by about 2 [V] than the reference voltage V_{ref}1 output from the first reference voltage power supply 175.

The control unit 178 is configured by, for example, a circuit such as a CPU. A plurality of output ports (I/O ports) of the CPU (the control unit 178) are connected to the plurality of corresponding input ports of the voltage generation circuit of the variable impedance unit 172. The control unit 178 adjusts the control voltage applied to the variable capacitor of the variable impedance unit 172 by appropriately changing the combinations of the potential states (the high state, the low state, and the open state) of the respective input ports. In this example, in this way, the impedance of the variable impedance unit 172 is adjusted.

The impedance of the variable impedance unit 172 is adjusted such that the direct-current voltage input to the constant voltage circuit 174 has a value substantially identical to the reference voltage V_{ref}1 output from the first reference voltage power supply 175. More specifically, when load current is increased and the alternating-current voltage of the secondary side transformer 171b is dropped, the control unit 178 decreases the impedance of the variable impedance unit 172. Further, when the voltage of the commercial power supply 180 is increased and the alternating-current voltage of the secondary side transformer 171b is raised, the control unit 178 increases the impedance of the variable impedance unit 172. Thus, since the alternating-current voltage input to the rectification circuit 173 is stabilized, the input voltage of the constant voltage circuit 174 can be controlled in a stable manner as a consequence.

In the power supply apparatus 170 with the above-described configuration, the rectification circuit 173 converts the alternating-current voltage dropped at the ratio corresponding the winding number between the primary side transformer 171a and the secondary side transformer 171b of the power supply transformer 171 into the direct-current voltage. Further, the constant voltage circuit 174 of a voltage dropping type generates the direct-current voltage with the constant voltage value based on the direct-current voltage output from the rectification circuit 173 and supplies the direct-current voltage with the constant voltage value to the load 181.

In the above-described power supply apparatus 170, according to the related art, the direct-current voltage output from the rectification circuit 173, that is, the input voltage of the constant voltage circuit 174 is varied due to the increase or decrease in the load current or the variation in the voltage of the primary side transformer 171a. As for the variation in the input voltage of the constant voltage circuit 174, the constant voltage circuit 174 of a voltage dropping type generally increases or decreases the voltage drop amount of the input voltage so that the voltage applied to the load 181 is equal to the reference voltage V_{ref}1 and stabilizes the voltage supplied to the load 181, as described above. In this case, the voltage drop amount of input voltage in the constant voltage circuit 174 becomes a power loss of the constant voltage circuit 174. That is, as the voltage drop amount of input voltage increases, the power loss of the constant voltage circuit 174 increases. Therefore, ideally, when the input voltage of the constant voltage circuit 174 can be controlled to be the minimum operation voltage (reference voltage V_{ref}1) of the constant voltage circuit 174, the power loss of the constant voltage circuit 174 can be minimized.

In contrast, in the power supply apparatus 170 of this example, as described above, the control unit 178 adjusts the impedance of the variable impedance unit 172, when the input voltage of the constant voltage circuit 174 is varied due to the increase or decrease in the load current or the variation in the voltage of the primary side transformer 171a. Specifically, the control unit 178 adjusts the impedance of the variable impedance unit 172 so that the input voltage of the constant voltage circuit 174 is substantially identical to the reference voltage V_{ref}1 output from the first reference voltage power supply 175. Accordingly, the power supply apparatus 170 of this example can perform the control such that the value of the input voltage of the constant voltage circuit 174 becomes the value of the minimum operation voltage (reference voltage V_{ref}1) of the constant voltage circuit 174. Thus, it is possible to minimize the power loss of the constant voltage circuit 174.

A power supply apparatus of a general voltage dropping type according to the related art stabilizes the input voltage of the constant voltage circuit by using the variable resistor. Therefore, the power loss is generated in the variable resistor. In this example, however, since the voltage is dropped by varying the capacitance of the variable capacitor of the variable impedance unit 172, the power loss of the resistant component is not generated. Thus, the power loss can be further reduced in the power supply apparatus 170 of this example than in the power supply apparatus according to the related art.

In this example, as described above, the circuit on the power input side of the variable impedance unit 172 is configured by the commercial power supply 180 and the power supply transformer 171, but the present disclosure is not limited thereto. For example, the circuit on the power input side of the variable impedance unit 172 may be configured by a switch power supply. For example, a power supply apparatus performing the same operation as that of the power supply apparatus 170 shown in FIG. 28 can be embodied by using a switch power supply of which an output is turned ON or OFF with a switching frequency of 100 kHz.

In the power supply apparatus 170 of this example, the output is performed by a single system, but the present disclosure is not limited thereto. For example, the power supply apparatus including a plurality of output systems (power system) can be configured by providing a plurality of output terminals of the power supply transformer.

### Fifth Application Example: Other Various Electronic Apparatuses

The voltage generation circuit according to the embodiments of the present disclosure may be applied to various electronic apparatuses in which the communication system, the wireless charging system, and the power supply apparatus described above in the second to fourth application examples are appropriately combined. In this case, the configurations of the transmission apparatus (communication apparatus unit) and the reception apparatus of the communication system embedded into the electronic apparatus are the same as those of the transmission apparatus 121 and the reception apparatus 122 described above in the second application example (see FIG. 26). The contactless communication is carried out with the outside.

Examples of an electronic apparatus including the communications system and the wireless charging system include a portable telephone, a smart phone, a tablet PC (Personal Computer), a note PC, a remote controller, and a wireless speaker. Further, examples of the electronic apparatus including the communication system and the wireless charging system include a camcorder, a digital camera, a portable audio player, 3D glasses, and a portable game console.

Examples of an electronic apparatus including the communication system and the power supply apparatus (power supply apparatus unit) include a tablet PC, a note PC, a desktop PC, a printer, a projector, a liquid crystal television, a home game apparatus, and a refrigerator. Further, examples of the electronic apparatus including the communication system and the power supply apparatus (power supply apparatus unit) include DVD (Digital Versatile Disc)/BD (Blu-ray Disc: registered trademark) players and DVD/BD recorders. Furthermore, the electronic apparatus including the communication system and the power supply apparatus (power supply apparatus unit) may be applied to an electric vehicle.

Examples of an electronic apparatus including the wireless charging system and the power supply apparatus (power supply apparatus unit) include a note PC, a portable television, a radio apparatus, a radio cassette recorder, an electric toothbrush, an electric shaver, and an iron. Further, the electronic apparatus including the wireless charging system and the power supply apparatus (power supply apparatus unit) may be applied to an electric vehicle.

Examples of an electronic apparatus including the communication system, the wireless charging system, and the power supply apparatus (power supply apparatus unit) include a note PC, a portable television, a radio apparatus, and a radio cassette recorder. Further, the electronic apparatus including the communication system, the wireless charging system, and the power supply apparatus (power supply apparatus unit) may be applied to an electric vehicle.

When the technique of the embodiments of the present disclosure described above is applied to the above-described various electronic apparatus, the same advantages can be obtained. In this case, various control units controlling each apparatus (systems) may be installed in each apparatus. When there are a plurality of control units commonly usable between apparatuses, the plurality of control units may be integrally configured.

For example, the voltage generation circuit according to the embodiments of the present disclosure may be applied to an adjustment apparatus used to adjust a frequency before the shipment of a contactless communication apparatus. In this case, the operation control of the voltage generation circuit can be performed by a processing circuit unit such as an LSI (Large Scale Integration) in the adjustment apparatus.

The present disclosure can be embodied with the following configurations.

(1) A voltage generation circuit includes: a resistor circuit which includes a plurality of resistors connected to each other in series or in parallel; a plurality of input ports which are connected in parallel to the resistor circuit and to which a control signal for controlling a potential state of the input port to one of a high state, a low state, and an open state is input; and an output port which is connected to the resistor circuit and outputs voltage signals with voltage values corresponding to combinations of the potential states of the plurality of input ports.

(2) In the voltage generation circuit described in (1), the resistor circuit is configured as a series circuit of the plurality of resistors. Both ends of the series circuit and connection points between the resistors in the series circuit are connected to the corresponding input ports, respectively. The output port is connected to the connection point between predetermined resistors among the resistors in the series circuit.

(3) In the voltage generation circuit described in (1), the resistor circuit is configured as a parallel circuit of the plurality of resistors. One terminal of each of the plurality of resistors is connected to the corresponding input port. The other terminal of each of the plurality of resistors is connected to the output port.

(4) In the voltage generation circuit described in (2), the number of states of the voltage values output from the output port is larger than the number of input ports.

(5) In the voltage generation circuit described in (2) or (4), when the potential state of the input port is in the high state, a voltage value of the input port is greater than a maximum voltage value of the voltage signal output from the output port.

(6) The voltage generation circuit described in any one of (2), (4), and (5) further includes: a plurality of output ports which are connected to the connection points between the plurality of different resistors in the series circuit; and a switch which selects a predetermined output port from the plurality of output ports.

(7) In the voltage generation circuit according to claim 3) or (4), when the potential state of the input port is in the high state, a voltage value of the input port is greater than a maximum voltage value of the voltage signal output from the output port.

(8) A resonance circuit includes: a voltage generation circuit including a resistor circuit which includes a plurality of resistors connected to each other in series or in parallel, a plurality of input ports which are connected in parallel to the resistor circuit and to which a control signal for controlling a potential state of the input port to one of a high state, a low state, and an open state is input, and an output port which is connected to the resistor circuit and outputs voltage signals with voltage values corresponding to combinations of the potential states of the plurality of input ports; and a variable capacitance element which is connected to the voltage generation circuit and of which a capacitance is varied in accordance with the voltage signal output from the output port.

(9) A communication apparatus includes: a voltage generation circuit which includes a resistor circuit which includes a plurality of resistors connected to each other in series or in parallel, a plurality of input ports which are connected in parallel to the resistor circuit and to which a control signal for controlling a potential state of the input port to one of a high state, a low state, and an open state is input, and an output port which is connected to the resistor circuit and outputs voltage signals with voltage values corresponding to combinations of the potential states of the plurality of input ports; a reception antenna unit which includes a resonance coil and a resonance capacitor including a variable capacitance element which is connected to the voltage generation circuit and of which a capacitance is varied in accordance with the voltage signal output from the output port and which carries out contactless communication with the outside; and a control unit which outputs the control signal to each of the plurality of input ports.

(10) A communication system includes: a transmission apparatus including a voltage generation circuit which includes a resistor circuit which includes a plurality of resistors connected to each other in series or in parallel, a plurality of input ports which are connected in parallel to the resistor circuit and to which a control signal for controlling a potential state of the input port to one of a high state, a low state, and an open state is input, and an output port which is connected to the resistor circuit and outputs voltage signals with voltage values corresponding to combinations of the potential states of the plurality of input ports, a reception antenna unit which includes a resonance coil and a resonance capacitor including a variable capacitance element which is connected to the voltage generation circuit and of which a capacitance is varied in accordance with the voltage signal output from the output port, and a control unit which outputs the control signal to each of the plurality of input ports; and a reception apparatus carrying out contactless communication with the transmission apparatus.

(11) A wireless charging system includes: a power feeding apparatus including a first voltage generation circuit which includes a first resistor circuit which includes a plurality of first resistors connected to each other in series or in parallel, a plurality of first input ports which are connected in parallel to the first resistor circuit and to which a control signal for controlling a potential state of the first input port to one of a high state, a low state, and an open state is input, and a first output port which is connected to the first resistor circuit and outputs voltage signals with voltage values corresponding to combinations of the potential states of the plurality of first input ports, a power feeding antenna unit which includes a first resonance coil and a first resonance capacitor including a first variable capacitance element which is connected to the first voltage generation circuit and of which a capacitance is varied in accordance with the voltage signal output from the first output port, and a first control unit which outputs the control signal to each of the plurality of first input ports; and a power receiving apparatus including a second voltage generation circuit which includes a second resistor circuit which includes a plurality of second resistors connected to each other in series or in parallel, a plurality of second input ports which are connected in parallel to the second resistor circuit and to which a control signal for controlling a potential state of the second input port to one of a high state, a low state, and an open state is input, and a second output port which is connected to the second resistor circuit and outputs voltage signals with voltage values corresponding to combinations of the potential states of the plurality of second input ports, a power receiving antenna unit includes a second resonance coil and a second resonance capacitor including a second variable capacitance element which is connected to the second voltage generation circuit and of which a capacitance is varied in accordance with the voltage signal output from the second output port and which carries out contactless communication with the power feeding antenna unit, and a second control unit which outputs the control signal to each of the plurality of second input ports.

(12) A power supply apparatus includes: a power supply unit; a rectification circuit unit which converts alternating-current power supplied from the power supply unit into direct-current power; a variable impedance unit which includes a voltage generation circuit including a resistor circuit which includes a plurality of resistors connected to each other in series or in parallel, a plurality of input ports which are connected in parallel to the resistor circuit and to which a control signal for controlling a potential state of the input port to one of a high state, a low state, and an open state is input, and an output port which is connected to the resistor circuit and outputs voltage signals with voltage values corresponding to combinations of the potential states of the plurality of input ports, and a variable capacitance element which is connected to the voltage generation circuit and of which a capacitance is varied in accordance with the voltage signal output from the output port and which is provided between the power supply unit and the rectification circuit unit; and a control unit which outputs the control signal to each of the plurality of input ports.

(13) An electronic apparatus includes: a voltage generation circuit which includes a resistor circuit which includes a plurality of resistors connected to each other in series or in parallel, a plurality of input ports which are connected in parallel to the resistor circuit and to which a control signal for controlling a potential state of the input port to one of a high state, a low state, and an open state is input, and an output port which is connected to the resistor circuit and outputs voltage signals with voltage values corresponding to combinations of the potential states of the plurality of input ports; a communication unit which includes a resonance coil and a resonance capacitor including a variable capacitance element which is connected to the voltage generation circuit and of which a capacitance is varied in accordance with the voltage signal output from the output port and which carries out contactless communication with the outside; and a control unit which outputs the control signal to each of the plurality of input ports.

(14) An electronic apparatus includes: a power feeding apparatus unit including a first voltage generation circuit which includes a first resistor circuit which includes a plurality of first resistors connected to each other in series or in parallel, a plurality of first input ports which are connected in parallel to the first resistor circuit and to which a control signal for controlling a potential state of the first input port to one of a high state, a low state, and an open state is input, and a first output port which is connected to the first resistor circuit and outputs voltage signals with voltage values corresponding to combinations of the potential states of the plurality of first input ports, a power feeding antenna unit which includes a first resonance coil and a first resonance capacitor including a first variable capacitance element which is connected to the first voltage generation circuit and of which a capacitance is varied in accordance with the voltage signal output from the first output port, and a first control unit which outputs the control signal to each of the plurality of first input ports; and a power receiving apparatus unit including a second voltage generation circuit which includes a second resistor circuit which includes a plurality of second resistors connected to each other in series or in parallel, a plurality of second input ports which are connected in parallel to the second resistor circuit and to which a control signal for controlling a potential state of the second input port to one of a high state, a low state, and an open state is input, and a second output port which is connected to the second resistor circuit and outputs voltage signals with voltage values corresponding to combinations of the potential states of the plurality of second input ports, a power receiving antenna unit includes a second resonance coil and a second resonance capacitor including a second variable capacitance element which is connected to the second voltage generation circuit and of which a capacitance is varied in accordance with the voltage signal output from the second output port and which carries out contactless communication with the power feeding antenna unit, and a second control unit which outputs the control signal to each of the plurality of second input ports.

(15) An electronic apparatus includes: a power supply unit; a rectification circuit unit which converts alternating-current power supplied from the power supply unit into direct-current power; a variable impedance unit which includes a voltage generation circuit including a resistor circuit which includes a plurality of resistors connected to each other in series or in parallel, a plurality of input ports which are connected in parallel to the resistor circuit and to which a control signal for controlling a potential state of the input port to one of a high state, a low state, and an open state is input, and an output port which is connected to the resistor circuit and outputs voltage signals with voltage values corresponding to combinations of the potential states of the plurality of input ports, and a variable capacitance element which is connected to the voltage generation circuit and of which a capacitance is varied in accordance with the voltage signal output from the output port and which is provided between the power supply unit and the rectification circuit unit; and a control unit which outputs the control signal to each of the plurality of input ports.

(16) An electronic apparatus includes: a communication apparatus unit including a first voltage generation circuit which includes a first resistor circuit which includes a plurality of first resistors connected to each other in series or in parallel, a plurality of first input ports which are connected in parallel to the first resistor circuit and to which a control signal for controlling a potential state of the first input port to one of a high state, a low state, and an open state is input, and a first output port which is connected to the first resistor circuit and outputs voltage signals with voltage values corresponding to combinations of the potential states of the plurality of first input ports, a resonance antenna unit includes a first resonance coil and a first resonance capacitor including a first variable capacitance element which is connected to the first voltage generation circuit and of which a capacitance is varied in accordance with the voltage signal output from the first output port, and a first control unit which outputs the control signal to each of the plurality of first input ports; a power feeding apparatus unit including a second voltage generation circuit which includes a second resistor circuit which includes a plurality of second resistors connected to each other in series or in parallel, a plurality of second input ports which are connected in parallel to the second resistor circuit and to which a control signal for controlling a potential state of the second input port to one of a high state, a low state, and an open state is input, and a second output port which is connected to the second resistor circuit and outputs voltage signals with voltage values corresponding to combinations of the potential states of the plurality of second input ports, a power feeding antenna unit includes a second resonance coil and a second resonance capacitor including a second variable capacitance element which is connected to the second voltage generation circuit and of which a capacitance is varied in accordance with the voltage signal output from the second output port, and a second control unit which outputs the control signal to each of the plurality of second input ports; and a power receiving apparatus unit including a third voltage generation circuit which includes a third resistor circuit which includes a plurality of third resistors connected to each other in series or in parallel, a plurality of third input ports which are connected in parallel to the third resistor circuit and to which a control signal for controlling a potential state of the third input port to one of a high state, a low state, and an open state is input, and a third output port which is connected to the third resistor circuit and outputs voltage signals with voltage values corresponding to combinations of the potential states of the plurality of third input ports, a power receiving antenna unit includes a third resonance coil and a third resonance capacitor including a third variable capacitance element which is connected to the third voltage generation circuit and of which a capacitance is varied in accordance with the voltage signal output from the third output port and which carries out contactless communication with the power feeding antenna unit, and a third control unit which outputs the control signal to each of the plurality of third input ports.

(17) An electronic apparatus includes: a communication apparatus unit including a first voltage generation circuit which includes a first resistor circuit which includes a plurality of first resistors connected to each other in series or in parallel, a plurality of first input ports which are connected in parallel to the first resistor circuit and to which a control signal for controlling a potential state of the first input port to one of a high state, a low state, and an open state is input, and a first output port which is connected to the first resistor circuit and outputs voltage signals with voltage values corresponding to combinations of the potential states of the plurality of first input ports, a resonance antenna unit includes a first resonance coil and a first resonance capacitor including a first variable capacitance element which is connected to the first voltage generation circuit and of which a capacitance is varied in accordance with the voltage signal output from the first output port, and a first control unit which outputs the control signal to each of the plurality of first input ports; and a power supply apparatus unit including a power supply unit, a rectification circuit unit which converts alternating-current power supplied from the power supply unit into direct-current power, a variable impedance unit which includes a second voltage generation circuit including a second resistor circuit which includes a plurality of second resistors connected to each other in series or in parallel, a plurality of second input ports which are connected in parallel to the second resistor circuit and to which a control signal for controlling a potential state of the second input port to one of a high state, a low state, and an open state is input, and a second output port which is connected to the second resistor circuit and outputs voltage signals with voltage values corresponding to combinations of the potential states of the plurality of second input ports and a second variable capacitance element which is connected to the second voltage generation circuit and of which a capacitance is varied in accordance with the voltage signal output from the second output port and which is provided between the power supply unit and the rectification circuit unit, and a second control unit which outputs the control signal to each of the plurality of second input ports.

(18) An electronic apparatus includes: a power feeding apparatus unit including a first voltage generation circuit which includes a first resistor circuit which includes a plurality of first resistors connected to each other in series or in parallel, a plurality of first input ports which are connected in parallel to the first resistor circuit and to which a control signal for controlling a potential state of the first input port to one of a high state, a low state, and an open state is input, and a first output port which is connected to the first resistor circuit and outputs voltage signals with voltage values corresponding to combinations of the potential states of the plurality of first input ports, a power feeding antenna unit includes a first resonance coil and a first resonance capacitor including a first variable capacitance element which is connected to the first voltage generation circuit and of which a capacitance is varied in accordance with the voltage signal output from the first output port, and a first control unit which outputs the control signal to each of the plurality of first input ports; a power receiving apparatus unit including a second voltage generation circuit which includes a second resistor circuit which includes a plurality of second resistors connected to each other in series or in parallel, a plurality of second input ports which are connected in parallel to the second resistor circuit and to which a control signal for controlling a potential state of the second input port to one of a high state, a low state, and an open state is input, and a second output port which is connected to the second resistor circuit and outputs voltage signals with voltage values corresponding to combinations of the potential states of the plurality of second input ports, a power receiving antenna unit includes a second resonance coil and a second resonance capacitor including a second variable capacitance element which is connected to the second voltage generation circuit and of which a capacitance is varied in accordance with the voltage signal output from the second output port and which carries out contactless communication with the power feeding antenna unit, and a second control unit which outputs the control signal to each of the plurality of second input ports; and a power supply apparatus unit including a power supply unit, a rectification circuit unit which converts alternating-current power supplied from the power supply unit into direct-current power, a variable impedance unit which includes a third voltage generation circuit including a third resistor circuit which includes a plurality of third resistors connected to each other in series or in parallel, a plurality of third input ports which are connected in parallel to the third resistor circuit and to which a control signal for controlling a potential state of the third input port to one of a high state, a low state, and an open state is input, and a third output port which is connected to the third resistor circuit and outputs voltage signals with voltage values corresponding to combinations of the potential states of the plurality of third input ports and a third variable capacitance element which is connected to the third voltage generation circuit and of which a capacitance is varied in accordance with the voltage signal output from the third output port and which is provided between the power supply unit and the rectification circuit unit, and a third control unit which outputs the control signal to each of the plurality of third input ports.

(19) An electronic apparatus includes: a communication apparatus unit including a first voltage generation circuit which includes a first resistor circuit which includes a plurality of first resistors connected to each other in series or in parallel, a plurality of first input ports which are connected in parallel to the first resistor circuit and to which a control signal for controlling a potential state of the first input port to one of a high state, a low state, and an open state is input, and a first output port which is connected to the first resistor circuit and outputs voltage signals with voltage values corresponding to combinations of the potential states of the plurality of first input ports, a resonance antenna unit includes a first resonance coil and a first resonance capacitor including a first variable capacitance element which is connected to the first voltage generation circuit and of which a capacitance is varied in accordance with the voltage signal output from the first output port, and a first control unit which outputs the control signal to each of the plurality of first input ports; a power feeding apparatus unit including a second voltage generation circuit which includes a second resistor circuit which includes a plurality of second resistors connected to each other in series or in parallel, a plurality of second input ports which are connected in parallel to the second resistor circuit and to which a control signal for controlling a potential state of the second input port to one of a high state, a low state, and an open state is input, and a second output port which is connected to the second resistor circuit and outputs voltage signals with voltage values corresponding to combinations of the potential states of the plurality of second input ports, a power feeding antenna unit includes a second resonance coil and a second resonance capacitor including a second variable capacitance element which is connected to the second voltage generation circuit and of which a capacitance is varied in accordance with the voltage signal output from the second output port, and a second control unit which outputs the control signal to each of the plurality of second input ports; a power receiving apparatus unit including a third voltage generation circuit which includes a third resistor circuit which includes a plurality of third resistors connected to each other in series or in parallel, a plurality of third input ports which are connected in parallel to the third resistor circuit and to which a control signal for controlling a potential state of the third input port to one of a high state, a low state, and an open state is input, and a third output port which is connected to the third resistor circuit and outputs voltage signals with voltage values corresponding to combinations of the potential states of the plurality of third input ports, a power receiving antenna unit includes a third resonance coil and a third resonance capacitor including a third variable capacitance element which is connected to the third voltage generation circuit and of which a capacitance is varied in accordance with the voltage signal output from the third output port and which carries out contactless communication with the power feeding antenna unit, and a third control unit which outputs the control signal to each of the plurality of third input ports; and a power supply apparatus unit including a power supply unit, a rectification circuit unit which converts alternating-current power supplied from the power supply unit into direct-current power, a variable impedance unit which includes a fourth voltage generation circuit including a fourth resistor circuit which includes a plurality of fourth resistors connected to each other in series or in parallel, a plurality of fourth input ports which are connected in parallel to the fourth resistor circuit and to which a control signal for controlling a potential state of the fourth input port to one of a high state, a low state, and an open state is input, and a fourth output port which is connected to the fourth resistor circuit and outputs voltage signals with voltage values corresponding to combinations of the potential states of the plurality of fourth input ports and a fourth variable capacitance element which is connected to the fourth voltage generation circuit and of which a capacitance is varied in accordance with the voltage signal output from the fourth output port and which is provided between the power supply unit and the rectification circuit unit, and a fourth control unit which outputs the control signal to each of the plurality of fourth input ports.

(20) An electronic apparatus includes: a voltage generation circuit which includes a resistor circuit which includes a plurality of resistors connected to each other in series or in parallel, a plurality of input ports which are connected in parallel to the resistor circuit and to which a control signal for controlling a potential state of the input port to one of a high state, a low state, and an open state is input, and an output port which is connected to the resistor circuit and outputs voltage signals with voltage values corresponding to combinations of the potential states of the plurality of input ports; a variable capacitance element which is connected to the voltage generation circuit and of which a capacitance is varied in accordance with the voltage signal output from the output port; and a control unit which outputs the control signal to each of the plurality of input ports.

It should be understood that various changes and modifications to the presently preferred embodiments described herein will be apparent to those skilled in the art. Such changes and modifications can be made without departing from the spirit and scope of the present subject matter and without diminishing its intended advantages. It is therefore intended that such changes and modifications be covered by the appended claims.

The invention is claimed as follows:

1. A voltage generation circuit comprising:
a resistor circuit which includes a plurality of resistors connected to each other in series or in parallel;
a plurality of input ports which are connected in parallel to the resistor circuit and to which a control signal for controlling a potential state of the input port to one of a high state, a low state, and an open state is input; and
an output port which is connected to the resistor circuit and outputs voltage signals with voltage values corresponding to combinations of the potential states of the plurality of input ports.

2. The voltage generation circuit according to claim 1,
wherein the resistor circuit is configured as a series circuit of the plurality of resistors,
wherein both ends of the series circuit and connection points between the resistors in the series circuit are connected to the corresponding input ports, respectively, and
wherein the output port is connected to the connection point between predetermined resistors among the resistors in the series circuit.

3. The voltage generation circuit according to claim 1,
wherein the resistor circuit is configured as a parallel circuit of the plurality of resistors,
wherein one terminal of each of the plurality of resistors is connected to the corresponding input port, and
wherein the other terminal of each of the plurality of resistors is connected to the output port.

4. The voltage generation circuit according to claim 2, wherein the number of states of the voltage values output from the output port is larger than the number of input ports.

5. The voltage generation circuit according to claim 2, wherein when the potential state of the input port is in the high state, a voltage value of the input port is greater than a maximum voltage value of the voltage signal output from the output port.

6. The voltage generation circuit according to claim 2, further comprising:
a plurality of output ports which are connected to the connection points between the plurality of different resistors in the series circuit; and
a switch which selects a predetermined output port from the plurality of output ports.

7. The voltage generation circuit according to claim 3, wherein when the potential state of the input port is in the high state, a voltage value of the input port is greater than a maximum voltage value of the voltage signal output from the output port.

8. A resonance circuit comprising:
a voltage generation circuit including a resistor circuit which includes a plurality of resistors connected to each other in series or in parallel, a plurality of input ports which are connected in parallel to the resistor circuit and to which a control signal for controlling a potential state of the input port to one of a high state, a low state, and an open state is input, and an output port which is connected to the resistor circuit and outputs voltage signals with voltage values corresponding to combinations of the potential states of the plurality of input ports; and
a variable capacitance element which is connected to the voltage generation circuit and of which a capacitance is varied in accordance with the voltage signal output from the output port.

9. A communication apparatus comprising:
a voltage generation circuit which includes a resistor circuit which includes a plurality of resistors connected to each other in series or in parallel, a plurality of input ports which are connected in parallel to the resistor circuit and to which a control signal for controlling a potential state of the input port to one of a high state, a low state, and an open state is input, and an output port which is connected to the resistor circuit and outputs voltage signals with voltage values corresponding to combinations of the potential states of the plurality of input ports;
a reception antenna unit which includes a resonance coil and a resonance capacitor including a variable capacitance element which is connected to the voltage generation circuit and of which a capacitance is varied in accordance with the voltage signal output from the output port and which carries out contactless communication with the outside; and
a control unit which outputs the control signal to each of the plurality of input ports.

10. A communication system comprising:
a transmission apparatus including
a voltage generation circuit which includes a resistor circuit which includes a plurality of resistors connected to each other in series or in parallel, a plurality of input ports which are connected in parallel to the resistor circuit and to which a control signal for controlling a potential state of the input port to one of a high state, a low state, and an open state is input, and an output port which is connected to the resistor circuit and outputs voltage signals with voltage values corresponding to combinations of the potential states of the plurality of input ports,
a reception antenna unit which includes a resonance coil and a resonance capacitor including a variable capacitance element which is connected to the voltage generation circuit and of which a capacitance is varied in accordance with the voltage signal output from the output port, and
a control unit which outputs the control signal to each of the plurality of input ports; and
a reception apparatus carrying out contactless communication with the transmission apparatus.

11. A wireless charging system comprising:
a power feeding apparatus including
a first voltage generation circuit which includes a first resistor circuit which includes a plurality of first resistors connected to each other in series or in parallel, a plurality of first input ports which are connected in parallel to the first resistor circuit and to which a control signal for controlling a potential state of the first input port to one of a high state, a low state, and an open state is input, and a first output port which is connected to the first resistor circuit and outputs voltage signals with voltage values corresponding to combinations of the potential states of the plurality of first input ports,
a power feeding antenna unit which includes a first resonance coil and a first resonance capacitor including a first variable capacitance element which is connected to the first voltage generation circuit and of which a capacitance is varied in accordance with the voltage signal output from the first output port, and
a first control unit which outputs the control signal to each of the plurality of first input ports; and
a power receiving apparatus including
a second voltage generation circuit which includes a second resistor circuit which includes a plurality of second resistors connected to each other in series or in parallel, a plurality of second input ports which are connected in parallel to the second resistor circuit and to which a control signal for controlling a potential state of the second input port to one of a high state, a low state, and an open state is input, and a second output port which is connected to the second resistor circuit and outputs voltage signals with voltage values corresponding to combinations of the potential states of the plurality of second input ports,
a power receiving antenna unit includes a second resonance coil and a second resonance capacitor including a second variable capacitance element which is connected to the second voltage generation circuit and of which a capacitance is varied in accordance with the voltage signal output from the second output port and which carries out contactless communication with the power feeding antenna unit, and
a second control unit which outputs the control signal to each of the plurality of second input ports.

12. A power supply apparatus comprising:
a power supply unit;
a rectification circuit unit which converts alternating-current power supplied from the power supply unit into direct-current power;
a variable impedance unit which includes a voltage generation circuit including a resistor circuit which includes a plurality of resistors connected to each other in series or in parallel, a plurality of input ports which are connected in parallel to the resistor circuit and to which a control signal for controlling a potential state of the input port to one of a high state, a low state, and an open state is input, and an output port which is connected to the resistor circuit and outputs voltage signals with voltage values corresponding to combinations of the potential states of the plurality of input ports, and a variable capacitance element which is connected to the voltage generation circuit and of which a capacitance is varied in accordance with the voltage signal output from the output port and which is provided between the power supply unit and the rectification circuit unit; and
a control unit which outputs the control signal to each of the plurality of input ports.

13. An electronic apparatus comprising:
a voltage generation circuit which includes a resistor circuit which includes a plurality of resistors connected to each other in series or in parallel, a plurality of input ports which are connected in parallel to the resistor circuit and to which a control signal for controlling a potential state of the input port to one of a high state, a low state, and an open state is input, and an output port which is connected to the resistor circuit and outputs voltage signals with voltage values corresponding to combinations of the potential states of the plurality of input ports;
a communication unit which includes a resonance coil and a resonance capacitor including a variable capacitance element which is connected to the voltage generation circuit and of which a capacitance is varied in accordance with the voltage signal output from the output port and which carries out contactless communication with the outside; and
a control unit which outputs the control signal to each of the plurality of input ports.

14. An electronic apparatus comprising:
a power feeding apparatus unit including
a first voltage generation circuit which includes a first resistor circuit which includes a plurality of first resistors connected to each other in series or in parallel, a plurality of first input ports which are connected in parallel to the first resistor circuit and to which a control signal for controlling a potential state of the first input port to one of a high state, a low state, and an open state is input, and a first output port which is connected to the first resistor circuit and outputs voltage signals with voltage values corresponding to combinations of the potential states of the plurality of first input ports,
a power feeding antenna unit which includes a first resonance coil and a first resonance capacitor including a first variable capacitance element which is connected to the first voltage generation circuit and of which a capacitance is varied in accordance with the voltage signal output from the first output port, and
a first control unit which outputs the control signal to each of the plurality of first input ports; and
a power receiving apparatus unit including
a second voltage generation circuit which includes a second resistor circuit which includes a plurality of second resistors connected to each other in series or in parallel, a plurality of second input ports which are connected in parallel to the second resistor circuit and to which a control signal for controlling a potential state of the second input port to one of a high state, a low state, and an open state is input, and a second output port which is connected to the second resistor circuit and outputs voltage signals with voltage values corresponding to combinations of the potential states of the plurality of second input ports,
a power receiving antenna unit includes a second resonance coil and a second resonance capacitor including a second variable capacitance element which is connected to the second voltage generation circuit and of which a capacitance is varied in accordance with the voltage signal output from the second output port and which carries out contactless communication with the power feeding antenna unit, and
a second control unit which outputs the control signal to each of the plurality of second input ports.

15. An electronic apparatus comprising:
a power supply unit;
a rectification circuit unit which converts alternating-current power supplied from the power supply unit into direct-current power;
a variable impedance unit which includes a voltage generation circuit including a resistor circuit which includes a plurality of resistors connected to each other in series or in parallel, a plurality of input ports which are connected in parallel to the resistor circuit and to which a control signal for controlling a potential state of the input port to one of a high state, a low state, and an open state is input, and an output port which is connected to the resistor circuit and outputs voltage signals with voltage values corresponding to combinations of the potential states of the plurality of input ports, and a variable capacitance element which is connected to the voltage generation circuit and of which a capacitance is varied in accordance with the voltage signal output from the output port and which is provided between the power supply unit and the rectification circuit unit; and
a control unit which outputs the control signal to each of the plurality of input ports.

16. An electronic apparatus comprising:
a communication apparatus unit including
a first voltage generation circuit which includes a first resistor circuit which includes a plurality of first resistors connected to each other in series or in parallel, a plurality of first input ports which are connected in parallel to the first resistor circuit and to which a control signal for controlling a potential state of the first input port to one of a high state, a low state, and an open state is input, and a first output port which is connected to the first resistor circuit and outputs voltage signals with voltage values corresponding to combinations of the potential states of the plurality of first input ports,
a resonance antenna unit includes a first resonance coil and a first resonance capacitor including a first variable capacitance element which is connected to the first voltage generation circuit and of which a capacitance is varied in accordance with the voltage signal output from the first output port, and
a first control unit which outputs the control signal to each of the plurality of first input ports;
a power feeding apparatus unit including
a second voltage generation circuit which includes a second resistor circuit which includes a plurality of second resistors connected to each other in series or in parallel, a plurality of second input ports which are connected in parallel to the second resistor circuit and to which a control signal for controlling a potential state of the second input port to one of a high state, a low state, and an open state is input, and a second output port which is connected to the second resistor circuit and outputs voltage signals with voltage values corresponding to combinations of the potential states of the plurality of second input ports,
a power feeding antenna unit includes a second resonance coil and a second resonance capacitor including a second variable capacitance element which is connected to the second voltage generation circuit and of which a capacitance is varied in accordance with the voltage signal output from the second output port, and
a second control unit which outputs the control signal to each of the plurality of second input ports; and
a power receiving apparatus unit including
a third voltage generation circuit which includes a third resistor circuit which includes a plurality of third resistors connected to each other in series or in parallel, a plurality of third input ports which are connected in parallel to the third resistor circuit and to which a control signal for controlling a potential state of the third input port to one of a high state, a low state, and an open state is input, and a third output port which is connected to the third resistor circuit and outputs voltage signals with voltage values corresponding to combinations of the potential states of the plurality of third input ports,
a power receiving antenna unit includes a third resonance coil and a third resonance capacitor including a third variable capacitance element which is connected to the third voltage generation circuit and of which a capacitance is varied in accordance with the voltage signal output from the third output port and which carries out contactless communication with the power feeding antenna unit, and
a third control unit which outputs the control signal to each of the plurality of third input ports.

17. An electronic apparatus comprising:
a communication apparatus unit including
a first voltage generation circuit which includes a first resistor circuit which includes a plurality of first resistors connected to each other in series or in parallel, a plurality of first input ports which are connected in parallel to the first resistor circuit and to which a control signal for controlling a potential state of the first input port to one of a high state, a low state, and an open state is input, and a first output port which is connected to the first resistor circuit and outputs voltage signals with voltage values corresponding to combinations of the potential states of the plurality of first input ports,
a resonance antenna unit includes a first resonance coil and a first resonance capacitor including a first variable capacitance element which is connected to the first voltage generation circuit and of which a capacitance is varied in accordance with the voltage signal output from the first output port, and
a first control unit which outputs the control signal to each of the plurality of first input ports; and
a power supply apparatus unit including
a power supply unit,
a rectification circuit unit which converts alternating-current power supplied from the power supply unit into direct-current power,
a variable impedance unit which includes a second voltage generation circuit including a second resistor circuit which includes a plurality of second resistors connected to each other in series or in parallel, a plurality of second input ports which are connected in parallel to the second resistor circuit and to which a control signal for controlling a potential state of the second input port to one of a high state, a low state, and an open state is input, and a second output port which is connected to the second resistor circuit and outputs voltage signals with voltage values corresponding to combinations of the potential states of the plurality of second input ports and a second variable capacitance element which is connected to the second voltage generation circuit and of which a capacitance is varied in accordance with the voltage signal output from the second output port and which is provided between the power supply unit and the rectification circuit unit, and
a second control unit which outputs the control signal to each of the plurality of second input ports.

18. An electronic apparatus comprising:
a power feeding apparatus unit including
a first voltage generation circuit which includes a first resistor circuit which includes a plurality of first resistors connected to each other in series or in parallel, a plurality of first input ports which are connected in parallel to the first resistor circuit and to which a control signal for controlling a potential state of the first input port to one of a high state, a low state, and an open state is input, and a first output port which is connected to the first resistor circuit and outputs voltage signals with voltage values corresponding to combinations of the potential states of the plurality of first input ports,
a power feeding antenna unit includes a first resonance coil and a first resonance capacitor including a first variable capacitance element which is connected to the first voltage generation circuit and of which a capacitance is varied in accordance with the voltage signal output from the first output port, and
a first control unit which outputs the control signal to each of the plurality of first input ports;
a power receiving apparatus unit including
a second voltage generation circuit which includes a second resistor circuit which includes a plurality of second resistors connected to each other in series or in parallel, a plurality of second input ports which are connected in parallel to the second resistor circuit and to which a control signal for controlling a potential state of the second input port to one of a high state, a low state, and an open state is input, and a second output port which is connected to the second resistor circuit and outputs voltage signals with voltage values corresponding to combinations of the potential states of the plurality of second input ports,
a power receiving antenna unit includes a second resonance coil and a second resonance capacitor including a second variable capacitance element which is connected to the second voltage generation circuit and of which a capacitance is varied in accordance with the voltage signal output from the second output port and which carries out contactless communication with the power feeding antenna unit, and
a second control unit which outputs the control signal to each of the plurality of second input ports; and
a power supply apparatus unit including
a power supply unit,
a rectification circuit unit which converts alternating-current power supplied from the power supply unit into direct-current power,
a variable impedance unit which includes a third voltage generation circuit including a third resistor circuit which includes a plurality of third resistors connected to each other in series or in parallel, a plurality of third input ports which are connected in parallel to the third resistor circuit and to which a control signal for controlling a potential state of the third input port to one of a high state, a low state, and an open state is input, and a third output port which is connected to the third resistor circuit and outputs voltage signals with voltage values corresponding to combinations of the potential states of the plurality of third input ports and a third variable capacitance element which is connected to the third voltage generation circuit and of which a capacitance is varied in accordance with the voltage signal output from the third output port and which is provided between the power supply unit and the rectification circuit unit, and
a third control unit which outputs the control signal to each of the plurality of third input ports.

19. An electronic apparatus comprising:
a communication apparatus unit including
a first voltage generation circuit which includes a first resistor circuit which includes a plurality of first resistors connected to each other in series or in parallel, a plurality of first input ports which are connected in parallel to the first resistor circuit and to which a control signal for controlling a potential state of the first input port to one of a high state, a low state, and an open state is input, and a first output port which is connected to the first resistor circuit and outputs voltage signals with voltage values corresponding to combinations of the potential states of the plurality of first input ports,
a resonance antenna unit includes a first resonance coil and a first resonance capacitor including a first variable capacitance element which is connected to the first voltage generation circuit and of which a capacitance is varied in accordance with the voltage signal output from the first output port, and
a first control unit which outputs the control signal to each of the plurality of first input ports;
a power feeding apparatus unit including
a second voltage generation circuit which includes a second resistor circuit which includes a plurality of second resistors connected to each other in series or in parallel, a plurality of second input ports which are connected in parallel to the second resistor circuit and to which a control signal for controlling a potential state of the second input port to one of a high state, a low state, and an open state is input, and a second output port which is connected to the second resistor circuit and outputs voltage signals with voltage values corresponding to combinations of the potential states of the plurality of second input ports,
a power feeding antenna unit includes a second resonance coil and a second resonance capacitor including a second variable capacitance element which is connected to the second voltage generation circuit and of which a capacitance is varied in accordance with the voltage signal output from the second output port, and
a second control unit which outputs the control signal to each of the plurality of second input ports;
a power receiving apparatus unit including
a third voltage generation circuit which includes a third resistor circuit which includes a plurality of third resistors connected to each other in series or in parallel, a plurality of third input ports which are connected in parallel to the third resistor circuit and to which a control signal for controlling a potential state of the third input port to one of a high state, a low state, and an open state is input, and a third output port which is connected to the third resistor circuit and outputs voltage signals with voltage values corresponding to combinations of the potential states of the plurality of third input ports,
a power receiving antenna unit includes a third resonance coil and a third resonance capacitor including a third variable capacitance element which is connected to the third voltage generation circuit and of which a capacitance is varied in accordance with the voltage signal output from the third output port and which carries out contactless communication with the power feeding antenna unit, and
a third control unit which outputs the control signal to each of the plurality of third input ports; and
a power supply apparatus unit including
a power supply unit,
a rectification circuit unit which converts alternating-current power supplied from the power supply unit into direct-current power,
a variable impedance unit which includes a fourth voltage generation circuit including a fourth resistor circuit which includes a plurality of fourth resistors connected to each other in series or in parallel, a plurality of fourth input ports which are connected in parallel to the fourth resistor circuit and to which a control signal for controlling a potential state of the fourth input port to one of a high state, a low state, and an open state is input, and a fourth output port which is connected to the fourth resistor circuit and outputs voltage signals with voltage values corresponding to combinations of the potential states of the plurality of fourth input ports and a fourth variable capacitance element which is connected to the fourth voltage generation circuit and of which a capacitance is varied in accordance with the voltage signal output from the fourth output port and which is provided between the power supply unit and the rectification circuit unit, and
a fourth control unit which outputs the control signal to each of the plurality of fourth input ports.

20. An electronic apparatus comprising:
a voltage generation circuit which includes a resistor circuit which includes a plurality of resistors connected to each other in series or in parallel, a plurality of input ports which are connected in parallel to the resistor circuit and to which a control signal for controlling a potential state of the input port to one of a high state, a low state, and an open state is input, and an output port which is connected to the resistor circuit and outputs voltage signals with voltage values corresponding to combinations of the potential states of the plurality of input ports;
a variable capacitance element which is connected to the voltage generation circuit and of which a capacitance is varied in accordance with the voltage signal output from the output port; and
a control unit which outputs the control signal to each of the plurality of input ports.
